(19) United States
(12) Patent Application Publication
(10) Pub. No.: US 2025/0275441 A1
(43) Pub. Date: Aug. 28, 2025

(54) DISPLAY PANEL AND DISPLAY DEVICE COMPRISING THE SAME

(71) Applicant: LG Display Co., Ltd., Seoul (KR)

(72) Inventors: Woong Jin SEO, Paju-si (KR); Chang Mo YANG, Paju-si (KR); Jung Geun JO, Paju-si (KR)

(21) Appl. No.: 18/975,707

(22) Filed: Dec. 10, 2024

(30) Foreign Application Priority Data
Feb. 23, 2024 (KR) 10-2024-0026588
Jul. 12, 2024 (KR) 10-2024-0092326

(51) Int. Cl. H10K 59/80; H10K 59/88

(52) U.S. Cl. CPC H10K 59/879; H10K 59/88

(57) ABSTRACT

Disclosed herein are a display panel and a display device including the same. The display panel includes: a first display area including a plurality of first pixels, a first viewing angle lens disposed on the plurality of first pixels, and a first dummy lens; and a second display area including a plurality of second pixels, a first viewing angle lens and a second viewing angle lens disposed on the plurality of second pixels, and a second dummy lens. The shape of the first dummy lens is different from the shape of the second dummy lens.

### CROSS-REFERENCE TO RELATED APPLICATION

This application claims priority to and the benefit of Korean Patent Applications No. 10-2024-0026588, filed Feb. 23, 2024, and Korean Patent Applications No. 10-2024-0092326, filed Jul. 12, 2024, the disclosure of which is incorporated herein by reference in its entirety.

### BACKGROUND

### Technical Field

The present specification relates to a display panel and a display device comprising the same.

### Description of the Related Art

A viewing angle variable technology is being applied to display devices. The variable viewing angle technology allows video content or visual information reproduced on a display device to be visible only to a user within a narrow viewing angle range, or to multiple users within a wide viewing angle range.

As the market for future vehicles such as electric vehicles and autonomous vehicles expands, the demand for in-vehicle display devices is growing rapidly. Research is being carried out into how the screen of an in-vehicle display device can be split so that one part of the screen is controlled at a narrow viewing angle and another part is controlled at a wide viewing angle. This technology may drive pixels with a narrow viewing angle, which are arranged in one part of the screen, to display personal content or information that only a specific user can see, and drive pixels with a wide viewing angle, which are arranged in another part of the screen, to display shared content that multiple users can see together.

### BRIEF SUMMARY

The present specification provides a display panel having uniform reflection properties of display areas and a display device comprising the same.

The present specification provides a display panel capable of adjusting a viewing angle according to display areas, and a display device comprising the same.

The technical features of the present specification are not limited to those mentioned above, and other technical features not mentioned will be clearly understood by those skilled in the art from the following description.

A display panel according to various embodiment of the present specification may include: a first display area including a plurality of first pixels, a first viewing angle lens disposed on the plurality of first pixels, and a first dummy lens; and a second display area including a plurality of second pixels, a first viewing angle lens and a second viewing angle lens disposed on the plurality of second pixels, and a second dummy lens, wherein the shape of the first dummy lens may be different from the shape of the second dummy lens.

According to various embodiment of the present specification, the sum of the area of the first viewing angle lens in the first display area and the area of the first dummy lens may be equal to the sum of the area of the first viewing angle lens in the second display area, the area of the second viewing angle lens in the second display area, and the area of the second dummy lens.

According to various embodiment of the present specification, the first pixel in the first display area may include a first-first subpixel, a first-second subpixel, and a first-third subpixel emitting light of different wavelengths, the second pixel may include a second-first subpixel, a second-second subpixel, and a second-third subpixel emitting light of different wavelengths, and the first-first subpixel to the first-third subpixel and the second-first subpixel to the second-third subpixel each may include a first light-emitting element and a second light-emitting element.

According to various embodiment of the present specification, the first viewing angle lens in the first display area may be disposed on the first light-emitting element and the second light-emitting element, the first viewing angle lens in the second display area may be disposed on the first light-emitting element, the second viewing angle lens in the second display area may be disposed on the second light-emitting element, and the shape of the first viewing angle lens may be different from the shape of the second viewing angle lens.

According to various embodiment of the present specification, the number of the first viewing angle lenses in the first display area may be greater than the number of the first viewing angle lenses in the second display area.

According to various embodiment of the present specification, the sum of the number of the first viewing angle lenses and the second viewing angle lenses in the second display area may be greater than the number of the first viewing angle lenses in the first display area.

According to various embodiment of the present specification, the first dummy lens may have the same shape as the second viewing angle lens in the second display area, the second dummy lens may have the same shape as the first viewing angle lens in the first display area.

According to various embodiment of the present specification, a position of the first dummy lens within the first pixel may correspond to a position of the second dummy lens within the second pixel.

According to various embodiment of the present specification, the shape of the second dummy lens may be different from the shape of the first viewing angle lens.

According to various embodiment of the present specification, the first light-emitting element and the second light-emitting element of the first pixel may be configured to drive simultaneously, and the first light-emitting element and the second light-emitting element of the second pixel may be configured to selectively drive according to modes.

According to various embodiment of the present specification, the display panel may further include: a third display area disposed between the first display area and the second display area, wherein the third display area may include a plurality of third pixels, a third viewing angle lens disposed on the plurality of third pixels, and a third dummy lens, and the shape of the third dummy lens may vary progressively from the first display area toward the second display area.

According to various embodiment of the present specification, the shape of the third viewing angle lens may vary progressively from the first display area toward the second display area.

A display panel according to various embodiment of the present specification may include: a first display area including a plurality of first pixels and a plurality of first viewing angle lenses disposed on the plurality of first pixels; a second display area including a plurality of second pixels, and a plurality of first viewing angle lenses and a plurality of second viewing angle lenses disposed on the plurality of second pixels; and a third display area including a plurality of third pixels, and a plurality of third viewing angle lenses and a plurality of fourth viewing angle lenses disposed on the plurality of third pixels, the third display area being disposed between the first display area and the second display area. The second display area may be configured to selectively emit any one of the first light-emitting element and the second light-emitting element disposed in each subpixel of the second pixel according to a first mode and a second mode in which the viewing angle is variable, the first display area may be configured to emit all of the first light-emitting element and the second light-emitting element disposed in each subpixel of the first pixel in the first mode and the second mode, and the shapes of the plurality of third viewing angle lenses and the plurality of fourth viewing angle lenses may vary progressively in a first direction from the first display area toward the second display area.

According to various embodiment of the present specification, the sum of the areas of the plurality of first viewing angle lenses in the first display area, the sum of the areas of the plurality of first viewing angle lenses and the plurality of second viewing angle lenses in the second display area, and the sum of the areas of the plurality of third viewing angle lenses and the plurality of fourth viewing angle lenses in the third display area are equal to each other.

A display device according to various embodiment of the present specification may include: a display panel; a data driver configured to drive the display panel; and a gate drive configured to drive the display panel. The display panel may include: a first display area including a plurality of first pixels, a plurality of first viewing angle lenses disposed on the plurality of first pixels, and a first dummy lens; and a second display area including a plurality of second pixels, a plurality of first viewing angle lenses and a plurality of second viewing angle lenses disposed on the plurality of second pixels, and a second dummy lens, wherein the first dummy lens and the second dummy lens have different shapes.

According to various embodiment of the present specification, the sum of the areas of the first viewing angle lenses in the first display area and the area of the first dummy lens may be equal to the sum of the areas of the first viewing angle lenses in the second display area, the areas of the second viewing angle lenses in the second display area, and the area of the second dummy lens.

According to various embodiment of the present specification, the first pixel may include a first-first subpixel, a first-second subpixel, and a first-third subpixel emitting light of different wavelengths, the second pixel may include a second-first subpixel, a second-second subpixel, and a second-third subpixel emitting light of different wavelengths, and the first-first subpixel to the first-third subpixel and the second-first subpixel to the second-third subpixel each may include a first light-emitting element and a second light-emitting element.

According to various embodiment of the present specification, the plurality of first viewing angle lenses in the first display area may be disposed on the first light-emitting element and the second light-emitting element, the plurality of the first viewing angle lenses in the second display area may be disposed on the first light-emitting element, the plurality of second viewing angle lenses in the second display area may be disposed on the second light-emitting element, and the shape of the first viewing angle lenses is different from the shape of the second viewing angle lenses.

A display panel according to various embodiment of the present specification may include: a first display area including a plurality of first pixels and a plurality of first viewing angle lenses disposed on the plurality of first pixels; a second display area including a plurality of second pixels, and a plurality of first viewing angle lenses and a plurality of second viewing angle lenses disposed on the plurality of second pixels; and a third display area including a plurality of third pixels, and a plurality of third viewing angle lenses and a plurality of fourth viewing angle lenses disposed on the plurality of third pixels, the third display area being disposed between the first display area and the second display area, wherein the first display area may be configured to emit all of the first light-emitting element and the second light-emitting element disposed in each subpixel of the first pixel according to a first mode and a second mode in which the viewing angle is variable, and the second display area may be configured to selectively emit any one of the first light-emitting element and the second light-emitting element disposed in each subpixel of the second pixel according to the first mode and the second mode, and wherein the emission area of the third pixel in the first mode may vary progressively in a first direction from the first display area toward the second display area.

According to various embodiment of the present specification, the first pixel may include a first-first subpixel, a first-second subpixel, and a first-third subpixel emitting light of different wavelengths, the second pixel may include a second-first subpixel, a second-second subpixel, and a second-third subpixel emitting light of different wavelengths, and the first-first subpixel to the first-third subpixel and the second-first subpixel to the second-third subpixel each may include a first light-emitting element and a second light-emitting element.

According to various embodiment of the present specification, the plurality of first viewing angle lenses in the first display area may be disposed on the first light-emitting element and the second light-emitting element, the plurality of the first viewing angle lenses in the second display area may be disposed on the first light-emitting element, the plurality of second viewing angle lenses in the second display area may be disposed on the second light-emitting element, and the shape of the first viewing angle lenses may be different from the shape of the second viewing angle lenses.

According to various embodiment of the present specification, the number of the first viewing angle lenses in the first display area may be greater than the number of the first viewing angle lenses in the second display area.

According to various embodiment of the present specification, the shapes of the plurality of third viewing angle lenses and the plurality of fourth viewing angle lenses may vary progressively in a first direction from the first display area toward the second display area.

According to various embodiment of the present specification, in the first mode, the number of light-emitting elements disposed and turned off in the third pixel varies progressively in the first direction.

According to various embodiment of the present specification, the third pixel may include a third-first subpixel, a third-second subpixel, and a third-third subpixel emitting light of different wavelengths, and the third-first subpixel to the third-third subpixel each may include a first light-emitting element and a second light-emitting element.

According to various embodiment of the present specification, the third display area may include: a third-first display area including a third-first pixel; and a third-second display area including a third-second pixel disposed in the first direction from the third-first pixel, wherein, in the first mode, the number of light-emitting elements disposed and turned off in the third-second pixel may be greater than the number of light-emitting elements disposed and turned off in the third-first pixel.

According to various embodiment of the present specification, the third-first subpixel to the third-third subpixel may be configured to implement any one color selected from the group consisting of red, green, and blue, respectively, without overlapping each other, and in the first mode, the third-second pixels may include: a third-second subpixel including a turned-off light-emitting element.

According to various embodiment of the present specification, the third display area may further includes: a third-third display area including a third-third pixel disposed in the first direction from the third-second pixel, and in the first mode, the third-third pixel may include: a third-second subpixel including a turned-off light-emitting element and a third-first subpixel including a turned-off light-emitting element.

According to various embodiment of the present specification, the third display area may further include: a third-fourth display area including a third-fourth pixel disposed in the first direction from the third-third pixel, and in the first mode, the third-fourth pixel may include: a third-second subpixel including a turned-off light-emitting element, a third-first subpixel including a turned-off light-emitting element, and a third-third subpixel including a turned-off light-emitting element.

According to various embodiment of the present specification, the third-first subpixels disposed in the third display area may implement the red color, the third-second subpixels disposed in the third display area may implement the green color, and third-third subpixels disposed in the third display area may implement the blue color.

According to various embodiment of the present specification, in the first mode, the emission area of the third pixel may decrease progressively in the first direction.

According to various embodiment of the present specification, the third pixel may include a third-first subpixel, a third-second subpixel, and a third-third subpixel emitting light of different wavelengths, the third-first subpixel to the third-third subpixel each may include a first light-emitting element and a second light-emitting element, and the shapes of the plurality of third viewing angle lenses and the plurality of fourth viewing angle lenses may vary progressively in the first direction.

According to various embodiment of the present specification, the plurality of the third viewing angle lenses may be disposed on the first light-emitting element, the plurality of fourth viewing angle lenses may be disposed on the second light-emitting element, and the shapes of the fourth viewing angle lenses may vary progressively in the first direction.

According to various embodiment of the present specification, in the first mode, the emission area of the second light-emitting element varies progressively in the first direction.

According to various embodiment of the present specification, the third pixel may include a third-first subpixel, a third-second subpixel, and a third-third subpixel emitting light of different wavelengths, the third-first subpixel to the third-third subpixel each includes a first light-emitting element and a second light-emitting element, and the third display area further includes a black matrix disposed on the second light-emitting element.

According to various embodiment of the present specification, the area in which the second light-emitting element disposed in the third display area and the black matrix overlap may vary progressively in the first direction.

According to the present specification, the reflection properties of the display areas may be uniform, thereby improving a problem of perceived visibility of a boundary between the respective display areas.

According to the present specification, the efficiency of the display device may be improved by allowing all pixels to be used in the display areas in which the viewing angle is not adjusted, thereby enabling low power operation may be possible.

The effects of the present specification are not limited to the above-mentioned effects, and other effects that are not mentioned will be apparently understood by those skilled in the art from the following description and the appended claims.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram illustrating a display device according to an embodiment of the present specification;

FIG. 2 is a diagram illustrating a state in which a display panel is divided into a plurality of display areas according to an embodiment of the present specification;

FIG. 3 is a circuit diagram illustrating a pixel circuit of the display device according to an embodiment of the present specification;

FIG. 4 is a circuit diagram illustrating a pixel circuit of the display device according to another embodiment of the present specification;

FIGS. 5 and 6 are diagrams illustrating pixels arranged in a first display area and a second display area of a display panel according to a first embodiment of the present specification;

FIGS. 7 to 8 are diagrams illustrating pixels arranged in a first display area and a second display area of a display panel according to a second embodiment of the present specification;

FIG. 9 is a cross-sectional view of a display panel according to an embodiment of the present specification;

FIG. 10 is a cross-sectional view of a display panel according to an embodiment of the present specification;

FIG. 11 is a cross-sectional view of a display panel according to an embodiment of the present specification;

FIG. 12 is a cross-sectional view of a display panel according to an embodiment of the present specification;

FIG. 13 is a cross-sectional view of a display panel according to an embodiment of the present specification;

FIG. 14 is a diagram illustrating a display device in which viewing angle lenses having the same shape are disposed in the first display area and the second display area;

FIG. 15 is a diagram illustrating a state in which the display device of FIG. 14 is driven in a first mode;

FIG. 16 is a diagram illustrating a state in which the display device of FIG. 14 is driven in a second mode;

FIG. 17 is a diagram illustrating a display device in which viewing angle lenses having different shapes are disposed in the first display area and the second display area;

FIG. 18 is a diagram illustrating a state in which the display device of FIG. 17 is driven in a first mode;

FIG. 19 is a diagram illustrating a state in which the display device of FIG. 17 is driven in a second mode;

FIG. 20 is a diagram illustrating that reflection properties of a first display area and a second display area are different from each other in the display device of FIG. 17;

FIG. 21 is a diagram illustrating a display device according to an embodiment of the present specification;

FIG. 22 is a diagram illustrating a state in which the display device of FIG. 21 is driven in a first mode;

FIG. 23 is a diagram illustrating a state in which the display device of FIG. 21 is driven in a second mode;

FIG. 24 is a diagram illustrating that reflection properties of a first display area and a second display area are similar to each other in the display device according to the embodiment of the present specification;

FIG. 25 is a diagram illustrating a first modified example of the display panel according to the first embodiment of the present specification;

FIG. 26 is a partial enlarged view of a portion A of FIG. 25;

FIG. 27 is a partial enlarged view of a portion B of FIG. 25;

FIG. 28 is a diagram illustrating a display panel according to a first modified example;

FIG. 29 is a diagram illustrating a second modified example of the display panel according to the first embodiment of the present specification;

FIG. 30 is a diagram illustrating the area of viewing angle lenses disposed on the display panel according to the second modified example;

FIG. 31 is a diagram illustrating a state in which a display device including the first modified example of the display panel according to the second embodiment of the present specification is driven in a first mode;

FIG. 32 is a circuit diagram illustrating a pixel circuit applicable to the first modified example of the display panel according to the second embodiment of the present specification;

FIG. 33 is a diagram illustrating a display device including the second modified example of the display panel according to the second embodiment of the present specification;

FIG. 34 is a diagram illustrating a display device including the second modified example of the display panel according to the second embodiment of the present specification;

FIG. 35 is a diagram illustrating a state in which a display device including a third modified example of the display panel according to the second embodiment of the present specification is driven in a first mode; and

FIG. 36 is a diagram illustrating a state in which a display device including a third modified example of the display panel according to the second embodiment of the present specification is driven in a second

### DETAILED DESCRIPTION

Advantages and features of the present specification and methods for achieving them will become clear with reference to embodiments described below in detail in conjunction with the accompanying drawings. However, the present specification is not limited to embodiments disclosed below but will be implemented in various different forms, these embodiments are merely provided to make the disclosure of the present specification complete and fully inform those skilled in the art to which the present specification pertains of the scope of the present specification.

Since shapes, sizes, ratios, angles, numbers, and the like disclosed in the drawings for describing the embodiments of the present specification are illustrative, the present specification is not limited to the illustrated items. The same reference number denotes the same components throughout the specification. In addition, in describing the present specification, when it is determined that the detailed description of a related known technology may unnecessarily obscure the gist of the present specification, detailed description thereof will be omitted. When “comprise,” “have,” “consist of,” or the like described herein are used, other parts may be added unless “only” is used. When a component is expressed in the singular, it includes a case in which the component is provided as a plurality of components unless specifically stated otherwise.

In construing a component, the component is construed as including the margin of error even when there is no separate explicit description about the margin of error.

When the positional relationship is described, for example, when the positional relationship between two parts is described using “on,” “above,” “under,” “next to,” or the like, one or more other parts may be positioned between the two parts unless “immediately” or “directly” is used.

When the temporal relationship is described, when the temporal relationship is described using “after,” “subsequently,” “then,” “before,” or the like, it may also include a non-consecutive case unless “immediately” or “directly” is used.

Although a first, a second, and the like are used to describe various components, these components are not limited by these terms. These terms are only used to distinguish one component from another component. Therefore, a first component described below may be a second component within the technical spirit of the present specification.

In the description of the components of the present specification, terms such as first, second, A, B, (a), and (b) may be used. These terms are only for the purpose of distinguishing one component from another component, and the nature, sequence, order, or the like of the corresponding component is not limited by these terms. When a certain component is described as being “connected,” “coupled,” or “joined” to another component, the certain component may be connected or joined directly to another component, but it should be understood that other components may be “interposed” between the certain component and another component, which may be connected or coupled indirectly unless otherwise stated specially.

It should be understood that “at least one” includes any combination of one or more of associated components. For example, “at least one of first, second, and third components” may include not only the first, second, or third component, but also any combination of two or more of the first, second, and third components.

In the following, various embodiments of the present specification will be described in detail with reference to the accompanying drawings.

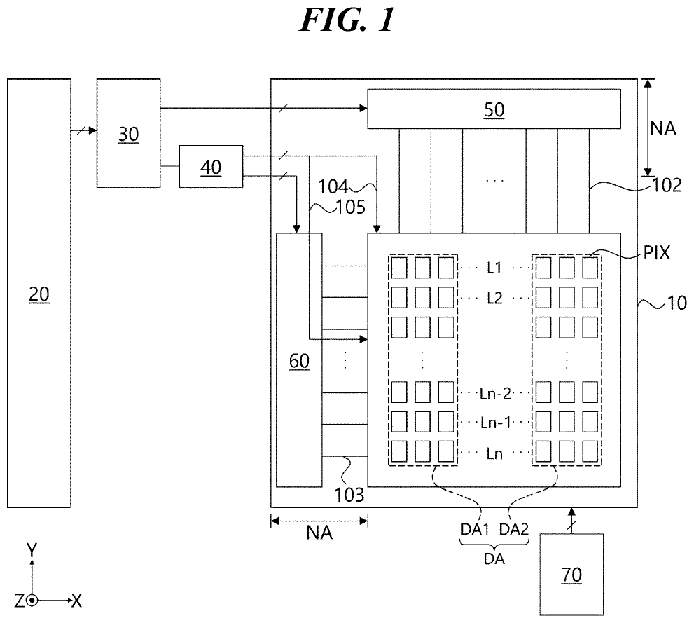

FIG. 1 is a block diagram illustrating a display device according to an embodiment of the present specification.

Referring to FIG. 1, a display device according to an embodiment of the present specification includes a display panel 10 and a display panel driving circuit for writing pixel data to pixels PIX of the display panel 10. The display device may include a power supply 70.

The display panel 10 may be, but is not limited to, a rectangular shaped panel having a length in the X-axis direction (or first direction), a width in the Y-axis direction (or second direction), and a thickness in the Z-axis direction (or third direction). For example, the display panel 10 may be a deformed panel that is at least partially curved or elliptical. It may also consist of multiple physically separated sub-panels.

A display area DA of the display panel 10 includes a pixel array for displaying an input image thereon. The pixel array includes a plurality of data lines 102, a plurality of gate lines 103 intersected with the data lines 102, and the pixels PIX arranged in a matrix form. The display panel 10 may further include power lines commonly connected to the pixels PIX. The power lines may be commonly connected to pixel circuits and supply a voltage for driving the pixels PIX to the pixels PIX.

Each of the pixels may be divided into a red subpixel (hereinafter referred to as a first subpixel), a green subpixel (hereinafter referred to as second subpixel), and a blue subpixel (hereinafter referred to as a third subpixel) for color implementation. Each of the pixels may further include a white subpixel. Each of the subpixels includes a pixel circuit to drive the light-emitting element. The light-emitting element may be implemented as, but is not limited to, an organic light-emitting element, such as an OLED, or an inorganic light-emitting element, such as a micro light-emitting diode (LED). Each of the pixel circuits may be connected to the data line, the gate lines, and the power lines. In the following, a pixel may be interpreted as a subpixel.

Each of the pixels PIX may include a first light-emitting element that emits in a first viewing angle mode (hereinafter referred to as “first mode”) and a second light-emitting element that emits in a second viewing angle mode (hereinafter referred to as “second mode”). Each of the pixels PIX may emit light from the first light-emitting element at a wide viewing angle in the first mode, whereas it may emit light from the second light-emitting element at a narrow viewing angle in the second mode.

The display area DA may include a first display area DA1 and a second display area DA2. The first display area DA1 may be an area that always operates in the first mode, and the second display area DA2 may be an area that is selectively driven in the first and second modes. For example, the first display area DA1 may be an area that always needs to display information, such as a car dashboard. The second display area DA2 may be an area where passengers can view a content image (movies, Internet, etc.). However, the embodiment of the present specification is not limited to those described above. For example, both the first display area DA1 and the second display area DA2 may be selectively operated in the first mode and the second mode.

The display array DA includes a plurality of pixel lines L1 to Ln. Each of the pixel lines L1 to Ln includes one line of pixels arranged along the line direction (X-axis direction) in the pixel array of the display panel 10. The pixels arranged in one pixel line may share the gate lines 103. The subpixels arranged in the column direction (Y) may share the same data line 102. One horizontal period is a time obtained by dividing one frame period by the total number of the pixel lines L1 to Ln.

The display panel 10 may be implemented as a non-transmissive display panel or a transmissive display panel. The transmissive display panel may be employed in a transparent display device in which an image is displayed on a screen and an actual object is visible beyond the display panel. The display panel 10 may be made as a flexible display panel that may be flexibly bent.

The power supply 70 receives an input voltage from a host system 20 and outputs voltages to drive the pixels PIX of the display panel 10 and the display panel driving circuit. To this end, the power supply 70 may include a direct current to direct current converter (DC-DC converter). The DC-DC converter may include a charge pump, a regulator, a buck converter, a boost converter, and the like. The power supply 70 may output constant voltages (or direct current voltages), such as a gate high voltage, a gate low voltage, a pixel driving voltage, a cathode voltage, a reference voltage, an initialization voltage, and an IC driving voltage for the display panel driving circuit through the DC-DC converter. The gate high voltage and the gate low voltage may be supplied to a level shifter 40 and a gate driver 60. The constant voltages such as the pixel driving voltage, the cathode voltage, the reference voltage, and the initialization voltage are supplied to the pixels PIX via the power lines commonly connected to the pixels PIX.

The power supply 70 may further include a gamma voltage generator. The gamma voltage generator may receive a high potential reference voltage and a low potential reference voltage and output a plurality of gamma reference voltages divided by a predetermined voltage difference interval on a preset gamma curve, for example, 2.2 gamma curve. The gamma reference voltages may be supplied to a data driver 50. In the data driver 50, the gamma reference voltages are divided by a voltage division circuit and subdivided into grayscale voltages. The gamma voltage generator may be implemented as a programmable gamma circuit capable of adjusting the respective gamma reference voltages according to digital data. A timing controller 30 or the host system 20 or a separate external device may update digital data to be stored in a register of the programmable gamma circuit through a communication interface.

The display panel driving circuit writes the pixel data of the input image to the pixels PIX of the display panel 10 under the control of the timing controller 30. The display panel driving circuit includes the data driver 50, a gate driver 60, a level shifter 40, and the timing controller 30.

The display panel driving circuit may further include a touch sensor driver for driving touch sensors. The touch sensor driver is omitted from FIG. 1. The data driver 50 and the touch sensor driver may be integrated into a source drive integrated circuit (IC).

The data driver 50 receives the pixel data of the input image received as a digital signal from the timing controller 30 and outputs a data voltage. The data driver 50 may receive the gamma reference voltages as its input and generate a gamma compensated voltage for each grayscale through the voltage division circuit. The gamma compensated voltage for each grayscale may be supplied to a digital-to-analog converter (hereinafter referred to as “DAC”) disposed on each of the channels of the data driver 50.

The data driver 50 samples and latches the digital data received from the timing controller 30, and then inputs the digital data to the DAC. Here, the digital data includes pixel data of the input image. The DAC converts the pixel data to the gamma compensated voltage and outputs the data voltage of the pixel data.

The gate driver 60 may be formed on the display panel 10 together with circuit elements of the display area DA and the wires. The gate driver 60 may be disposed in the non-display area NA on at least one of the right or left sides outside the display area AA in the display panel 10, or at least a portion thereof may be disposed within the display area DA.

The gate driver 60 may be disposed in the non-display areas NA on both sides of the display panel 10 with the display area DA of the display panel interposed therebetween, and may supply gate pulses from both sides of the gate lines 103 in a double feeding method. In another embodiment, the gate driver 60 may be disposed in at least one of the left and right non-display areas NA of the display panel 10 to supply gate signals to the gate lines 103 in a single feeding method. The gate driver 60 sequentially outputs pulses of the gate signals to the gate lines 103 under the control of the timing controller 30. The gate driver 60 may sequentially supply the gate signals to the gate lines 103 by shifting the pulses of the gate signals using a shift register or an edge trigger.

The gate signal may include a scan signal inputted to the pixel circuit via a plurality of gate lines, and an emission signal (hereinafter referred to as an “EM signal”). In this case, the gate driver may include a gate driving part that outputs the scan signal and a gate driving part that outputs the EM signal. Each of the scan signal and the EM signal may swing between the gate high voltage and the gate low voltage.

The timing controller 30 receives digital video data of the input image and a timing signal synchronized with the digital video data from the host system 20. The timing signal may include a vertical synchronization signal Vsync, a horizontal synchronization signal Hsync, and a data enable signal DE. A vertical period and a horizontal period may be known by a method of counting the data enable signal DE, and thus the vertical synchronization signal Vsync and the horizontal synchronization signal Hsync may be omitted. The horizontal synchronization signal Hsync and the data enable signal DE have a period of one horizontal period (1H).

The timing controller 30 generates a data timing control signal for controlling the operation timing of the data driver 50 and a gate timing control signal for controlling the operation timing of the gate driver 60 based on the timing signals Vsync, Hsync, and DE received from the host system 20 in order to control the display panel driving circuit. The timing controller 30 may synchronize the data driving circuit 50 and the gate driver 60 by controlling the operation timing of the display panel driving circuit.

The gate timing control signal output from the timing controller 30 may be inputted to the shift register of the gate driver 60 through the level shifter 40. A mode selection signal outputted from the timing controller 30 may be inputted to a mode selection circuit through the level shifter 40. The mode selection signal may include a vertical mode selection signal, a horizontal mode selection signal, and a bridge signal.

The level shifter 40 may convert a voltage level of the signal received from the timing controller 30 to a swing width between the gate high voltage and the gate low voltage and output the same. The level shifter 40 may decode the gate timing signal to output a start pulse and clock to drive the gate driver 60, and may decode the mode selection signal to output the vertical mode selection signal, the horizontal mode selection signal, and the bridge signal. The start pulse, clock, vertical mode select signal, horizontal mode select signal, and bridge signal are each alternating current signals that swing between the gate high and gate low voltages.

The host system 20 may scale an image signal from a video source to match the resolution of the display panel 10, and may transmit it to the timing controller 30 together with the timing control signal. The host system 20 may transmit a viewing angle mode signal having different logic values in the first mode and the second mode together with the image signal to the timing controller 30 at least once every frame. The timing controller 30 may output the vertical mode selection signal, the horizontal mode selection signal, and the bridge signal in response to the viewing angle mode signal.

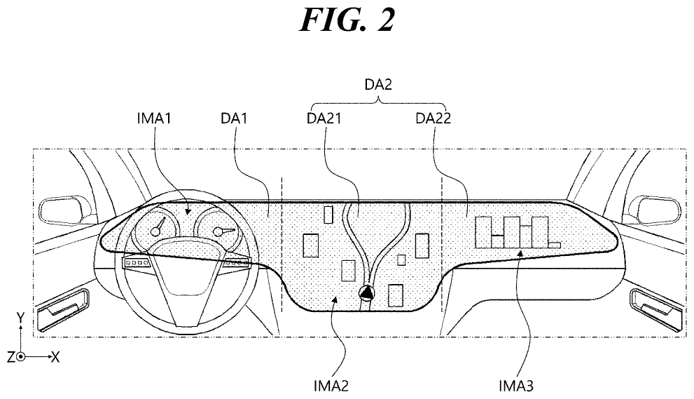

FIG. 2 is a diagram illustrating a state in which a display panel is divided into a plurality of display areas according to an embodiment of the present specification.

Referring to FIG. 2, the display device may be an in-vehicle display disposed on the front of a vehicle. However, the embodiment of the present specification is not limited to that described above. The display may include a first display area DA1 disposed in front of the driver to provide an image IMA1 relating to the safety of the vehicle, such as the speed of the vehicle, and a second display area DA2 disposed in front of a passenger seat to provide images IMA2 and IMA3 which may be viewed jointly by the driver and the passengers. The viewing angle of the second display area DA2 may be adjusted so as not to interfere with driving while the vehicle is in motion.

The second display area DA2 may include a second-second display area DA22 disposed in front of the passenger seat and a second-first display area DA21 disposed between the first display area DA1 and the second-second display area DA22. When a navigation image IMA2 is output to the second-first display area DA21, the second-first display area DA21 may be operated in the first mode so that the driver may view it. However, when images other than the navigation image are output, the second-first display area DA21 may operate in the second mode. The first mode may be a mode in which the light output from the display panel has a wide viewing angle so that both the driver and the passengers can see it. On the contrary, the second mode may be a mode in which the image output from the display panel has a narrow viewing angle, so that the driver cannot see the image.

The passengers may enjoy a variety of content images through the second-second display area DA22 while the vehicle is in motion. For example, content images such as movies, news, etc., may be output to the second-second display area DA22. These images may be distracting the driver while driving, so in some implementations, the second-second display area is operated in the second mode so that the driver cannot see them.

The first display area DA1, on the other hand, may always be used in the first mode because it must provide the driver and/or the passengers with information relating to the driving of the vehicle.

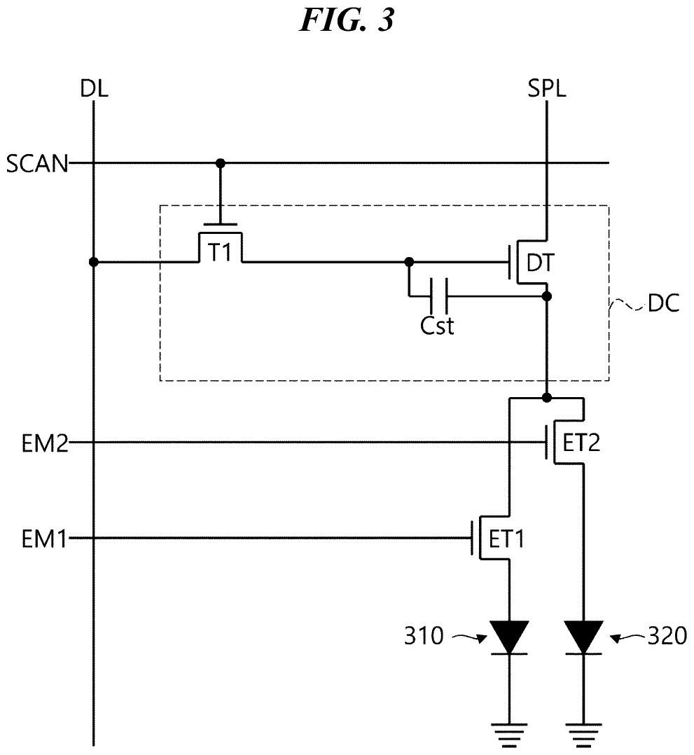

FIG. 3 is a circuit diagram illustrating a pixel circuit of the display device according to an embodiment of the present specification.

Referring to FIG. 3, a pixel circuit of the pixels PIX may include a plurality of transistors DT, T1, ET1, and ET2, a capacitor Cst, and a plurality of light-emitting elements 310 and 320.

A driving transistor DT and the capacitor Cst may be connected to the first switching transistor T1. A first electrode of the driving transistor DT may be connected to a driving voltage supply line SPL.

A first switching transistor T1 may be connected to a gate line SCAN to receive a gate signal. The first switching transistor T1 may be turned on or off by the gate signal. A first electrode of the first switching transistor T1 may be connected to a data line DL. In response to the first switching transistor T1 being turned on, a data signal may be supplied through the first switching transistor T1 to a gate electrode of the driving transistor DT.

The capacitor Cst may be disposed between the gate electrode and a second electrode of the driving transistor DT. The capacitor Cst may maintain a signal, such as a data signal, applied to the gate electrode of the driving transistor DT for one or more frames.

According to the embodiment, the driving transistor DT, the first switching transistor T1, and the capacitor Cst are components for driving the emission of first and second light-emitting elements 310 and 320, and may be defined as a driver DC.

The first light-emitting element 310 may be connected to a first emission control transistor ET1 that is turned on or turned off by a first emission control signal supplied via a first emission control line EM1. The second light-emitting element 320 may be connected to a second emission control transistor ET2 that is turned on or turned off by a second emission control signal supplied via a second emission control line EM2. The driver DC of the pixel circuit may further include first and second emission control transistors ET1 and ET2.

The first light-emitting element 310 or the second light-emitting element 320 may be connected to other configurations of the pixel circuit, such as the driving transistor DT, according to the modes. The modes may be specified by user input or determined when a predetermined condition is satisfied. For example, when a first predetermined condition is satisfied, the first emission control signal may be enabled to cause the first light-emitting element 310 to be turned on to emit light. When a second predetermined condition is satisfied, the second emission control signal may be enabled to cause the second light-emitting element 320 to turn on to emit light. The first condition may include a predetermined condition for driving the first mode. The second condition may include a predetermined condition for driving the second mode.

Regardless of the modes, the first emission control signal and the second emission control signal may always be applied to the first light-emitting element 310 and the second light-emitting element 320 disposed in the first display area DA1. Thus, the first light-emitting element 310 and the second light-emitting element 320 of the first display area DA1 may always be turned on when the vehicle is traveling.

The first light-emitting element 310 and the second light-emitting element 320 disposed in the second display area DA2 may be selectively turned on according to the first mode or the second mode.

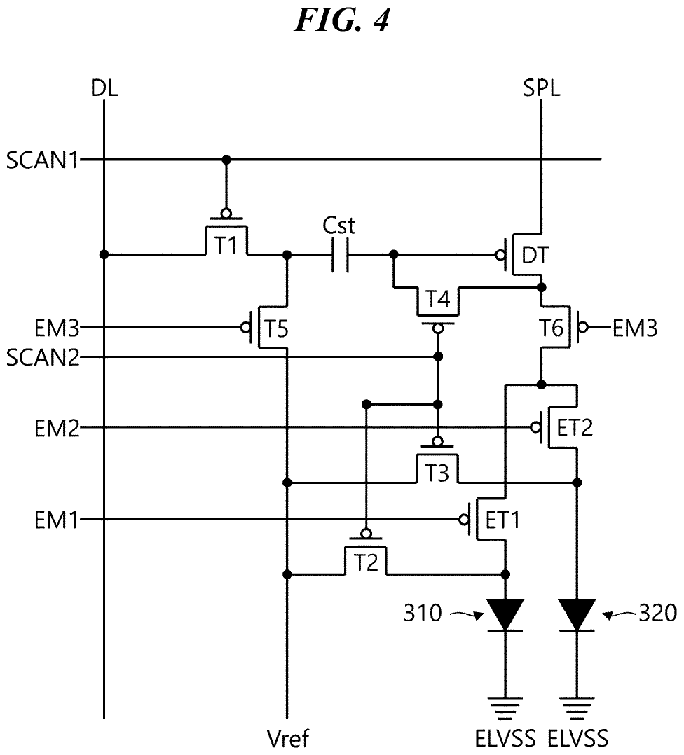

FIG. 4 is a circuit diagram illustrating a pixel circuit of the display device according to another embodiment of the present specification. The same or similar reference numerals are given to the components that function substantially the same as or similar to the embodiments described above, and descriptions thereof are omitted.

Referring to FIG. 4, a pixel circuit of the pixels PIX may include a plurality of transistors DT, T1, ET1, and ET2, a capacitor Cst, and a plurality of light-emitting elements 310 and 320.

The plurality of transistors DT, T1, T2, T3, T4, T5, T6 ET1, and ET2 may be implemented as P-type transistors, but the embodiment of the present specification is not limited thereto.

The first switching transistor T1 may be connected to a first gate line SCAN1 to be supplied with a gate signal. A first electrode of the first switching transistor T1 may be connected to a data line DL, a second electrode thereof may be connected to a first electrode of the capacitor Cst, and a gate electrode thereof may be connected to the first gate line SCAN1. The first switching transistor T1 may be turned on or turned off by the gate signal supplied via the first gate line SCAN1. In response to the first switching transistor T1 being turned on, a data signal may be supplied through the first switching transistor T1 to a gate electrode of the driving transistor DT.

A first electrode of a second switching transistor T2 may be connected to a reference voltage line Vref, a second electrode thereof may be connected to a first electrode of the first light-emitting element 310, and a gate electrode thereof may be connected to a second gate line SCAN2.

A first electrode of a third switching transistor T3 may be connected to the reference voltage line Vref, a second electrode thereof may be connected to a first electrode of the second light-emitting element 320, and a gate electrode thereof may be connected to the second gate line SCAN2.

A first electrode of a fourth switching transistor T4 may be connected to a second electrode of the capacitor Cst, a second electrode thereof may be connected to the second electrode of the driving transistor DT, and a gate electrode thereof may be connected to the second gate line SCAN2.

A first electrode of a fifth switching transistor T5 may be connected to the first electrode of the capacitor Cst, a second electrode thereof may be connected to the reference voltage line Vref, and a gate electrode thereof may be connected to a third emission control line EM3.

A first electrode of a sixth switching transistor T6 may be connected to the second electrode of the driving transistor DT, a second electrode thereof may be connected to first electrodes of the emission control transistors ET1 and ET2, and a gate electrode thereof may be connected to the third emission control line EM3.

The driving transistor DT may supply a driving voltage to the light-emitting elements 310 and 320 of response to a data signal supplied from the first switching transistor T1. A gate electrode of the driving transistor DT may be connected to the second electrode of the capacitor Cst, a first electrode thereof may be connected to a driving voltage supply line SPL, and the second electrode thereof may be connected to the first electrode of the sixth switching transistor T6.

The first emission control transistor ET1 may supply the driving voltage to the first light-emitting element 310 of response to a light emission control signal supplied from a first emission control line EM1. A gate electrode of the first emission control transistor ET1 may be connected to the first emission control line EM1, a first electrode thereof may be connected to the second electrode of the sixth switching transistor T6, and a second electrode may be connected to the first electrode of the first light-emitting element 310.

The second emission control transistor ET2 may supply a driving voltage to the second light-emitting element 320 of response to a light emission control signal supplied from a second emission control line EM2. A gate electrode of the second emission control transistor ET2 may be connected to the second emission control line EM2, a first electrode thereof may be connected to the second electrode of the sixth switching transistor T6, and a second electrode thereof may be connected to the first electrode of the second light-emitting element 320.

The capacitor Cst may be disposed between the first switching transistor T1 and the driving transistor DT. The first electrode of the capacitor Cst may be connected to the second electrode of the first switching transistor, and a second electrode thereof may be connected to the gate electrode of the driving transistor DT. The capacitor Cst may hold a signal, such as a data signal, applied to the gate electrode of the driving transistor DT for one or more than one frames.

The first light-emitting element 310 may be connected to the first emission control transistor ET1 that is turned on or turned off by a first emission control signal EM1. The second light-emitting element 320 may be connected to the second emission control transistor ET2 that is turned on or turned off by a second emission control signal EM2.

The first light-emitting element 310 or the second light-emitting element 320 may be connected to other configurations of the pixel circuit, such as the driving transistor DT, according to the modes.

Regardless of the modes, the first emission control signal and the second emission control signal may always be applied to the first light-emitting element 310 and the second light-emitting element 320 disposed in the first display area DA1. Thus, the first light-emitting element 310 and the second light-emitting element 320 of the first display area DA1 may always be turned on.

The first light-emitting element 310 and the second light-emitting element 320 disposed in the second display area DA2 may be selectively turned on according to the first mode or the second mode.

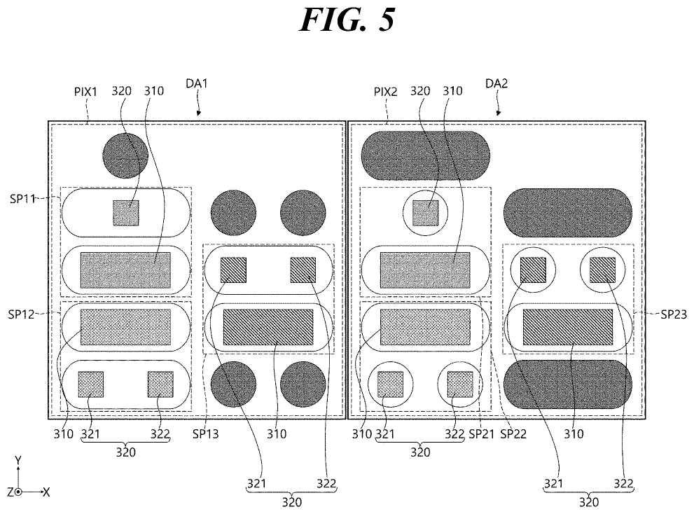

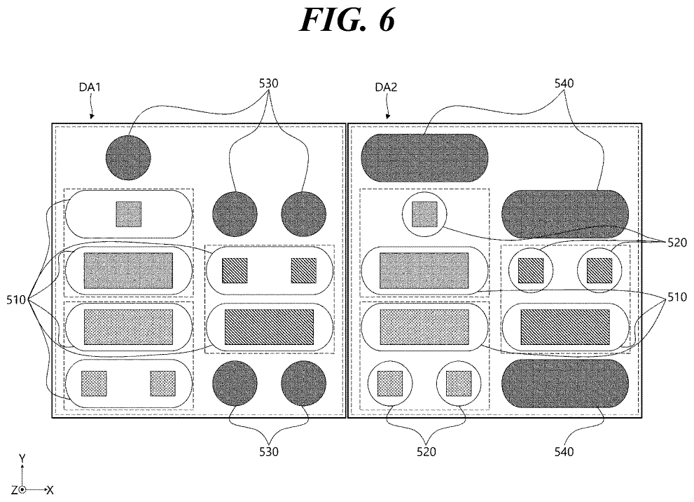

FIGS. 5 and 6 are diagrams illustrating pixels arranged in a first display area and a second display area of a display panel according to a first embodiment of the present specification. FIGS. 5 and 6 use different reference numerals to illustrate their respective configurations. For example, FIG. 6 refers to various lenses that are not referenced in FIG. 5.

Referring to FIGS. 5 and 6, a first display area DA1 may include a plurality of first pixels PIX1, a first viewing angle lens 510 disposed on the plurality of first pixels PIX1, and a first dummy lens 530. The second display area DA2 may include a plurality of second pixels PIX2, a first viewing angle lens 510 and a second viewing angle lens 520 disposed on the plurality of second pixels PIX2, and a second dummy lens 540.

The first display area DA1 and the second display area DA2 may be, but are not limited to, separate areas for displaying different images on a single display panel. The first display area DA1 and the second display area DA2 may be physically separate areas.

For ease of illustration, one first pixel PIX1 is shown arranged in the first display area DA1 and one second pixel PIX2 is shown arranged in the second display area DA2, but a plurality of pixels may be arranged in the first display area DA1 and the second display area DA2.

The plurality of first pixels PIX1 may include a first-first subpixel SP11 that outputs red light, a first-second subpixel SP12 that outputs green light, and a first-third subpixel SP13 that outputs blue light.

The first-first subpixel to the first-third subpixel SP11, SP12, and SP13 may each include a first light-emitting element 310 and a second light-emitting element 320. The light-emitting elements in the first-first to the first-third subpixels SP11, SP12, and SP13 may output different colors of light. For example, the first light-emitting element 310 and the second light-emitting element 320 of the first-first subpixel SP11 may emit red light, the first light-emitting element 310 and the second light-emitting element 320 of the first-second subpixel SP12 may emit green light, and the first light-emitting element 310 and the second light-emitting element 320 of the first-third subpixel SP13 may emit blue light.

The size and/or shape of the first light-emitting element 310 of the first-first subpixel SP11 may be different from that of the second light-emitting element 320. For example, the first light-emitting element 310 may have a rectangular shape with a predetermined length, and the second light-emitting element 320 may have a square shape. For example, the size of the first light-emitting element 310 may be twice the size of the second light-emitting element 320. However, the embodiment of the present specification is not limited to those described above. The first light-emitting element 310 and the second light-emitting element 320 may be the same size. In addition, the number of the second light-emitting element 320 of the first-first subpixel SP11 may be two.

The first viewing angle lens 510 may be disposed on the first light-emitting element 310 and the second light-emitting element 320 of the first-first subpixel SP11. The first viewing angle lens 510 may be a wide viewing angle lens. Thus, the light output from the first light-emitting element 310 and the second light-emitting element 320 of the first-first subpixel SP11 may have a wide viewing angle.

Since the first-first subpixel SP11 is driven by two light-emitting elements, the desired luminance may be maintained even when the voltage level is reduced by half compared to the driving of a single light-emitting element. This may enable low-power operation.

The first viewing angle lens 510 may be formed to be elongated in one direction and to be larger than the area of the first light-emitting element 310 and the second light-emitting element 320 of the first subpixel SP11 on a plane. However, the embodiment is not limited thereto, and the first viewing angle lens 510 may have, without limitation, a variety of shapes of lens structures capable of widening the viewing angle.

Each of the first-second subpixel SP12 and the first-third subpixel SP13 may include the first light-emitting element 310 and the second light-emitting element 320. The second light-emitting element 320 of the first-second subpixel SP12 and the first-third subpixel SP13 may include a second-first light-emitting element 321 and a second-second light-emitting element 322 spaced apart from each other. The second-first light-emitting element 321 and the second-second light-emitting element 322 may have the same size, but are not necessarily limited to the same size. For example, the second-first light-emitting element 321 may be larger or smaller than the second-second light-emitting element 322. Alternatively, the second light-emitting element 320 may consist of a single light-emitting element.

The first viewing angle lens 510 may be disposed on both the first light-emitting element 310 and the second light-emitting element 320 of the first-second subpixels SP12 and the first-third subpixels SP13. Since the first-second subpixel SP12 and the first-third subpixel SP13 are driven by the first light-emitting element 310 and the second light-emitting element 320, the desired luminance may be maintained even when the voltage level applied to each light-emitting element is reduced. This may enable low-power operation.

The plurality of second pixels PIX2 disposed in the second display area DA2 may include a second-first subpixel SP21 that outputs red light, a second-second subpixel SP22 that outputs green light, and a second-third subpixel SP23 that outputs blue light.

The second-first subpixel to the second-third subpixel SP21, SP22, and SP23 may include the first light-emitting element 310 and the second light-emitting element 320 that may be selectively driven. The first light-emitting element 310 and the second light-emitting element 320 of the second-first subpixel SP21 may emit red light, the first light-emitting element 310 and the second light-emitting element 320 of the second-second subpixel SP22 may emit green light, and the first light-emitting element 310 and the second light-emitting element 320 of the second-third subpixel SP23 may emit blue light.

The size and/or shape of the first light-emitting elements 310 of the second-first subpixel to second-third subpixel SP21 and SP22, and SP23 may be different from that of the second light-emitting elements 320. For example, the size of the first light-emitting elements 310 may be twice the size of the second light-emitting elements 320, but the embodiments are not limited thereto. For example, size and/or shape of the first light-emitting element 310 of the second-first subpixel to second-third subpixel SP21 and SP22, and SP23 may be the same as that of the second light-emitting element 320.

A first viewing angle lens 510 and a second viewing angle lens 520 may be disposed on the first light-emitting element 310 and the second light-emitting element 320 of the second-first subpixel SP21. The first viewing angle lens 510 may be disposed on the first light-emitting element 310. The second viewing angle lens 520 may be disposed on the second light-emitting element 320. Accordingly, the light emitted from the first light-emitting element 310 of the second-first subpixel SP21 may have a wide viewing angle, while the light emitted from the second light-emitting element 320 may have a narrow viewing angle and may be seen only from the front and not from the sides.

Each of the second-second subpixel SP22 and the second-third subpixel SP23 may include the first light-emitting element 310 and the second light-emitting element 320. The second light-emitting elements 320 of the second-second subpixel SP22 and the second-third subpixels SP23 may include a second-first light-emitting element 321 and a second-second light-emitting element 322 spaced apart from each other. The second-first light-emitting element and the second-second light-emitting element may have the same size, but are not necessarily limited to the same size. For example, the second-first light-emitting element may be larger or smaller than the second-second light-emitting element.

The first viewing angle lens 510 may be disposed on the first light-emitting elements 310 of the second-second subpixel SP22 and the second-third subpixel SP23, and the second viewing angle lens 520 may be disposed on the second light-emitting elements 320 of the second-second subpixel SP22 and the second-third subpixel SP23.

The first light-emitting elements 310 and the second light-emitting element 320 of the second-first subpixel to the second-third subpixel SP21, SP22, and SP23 may be selectively driven according to the modes. As an example, in the first mode, only the first light-emitting element 310 may be turned on. As a result, the image output from the second display area DA2 may be visually perceived at a relatively wide angle. However, in the second mode of controlling the viewing angle, only the second light-emitting element 320 is turned on, so that the image output from the second display area DA2 may only be visually perceived at a relatively narrow angle.

According to an embodiment, in the first display area DA1, the first light-emitting element 310 and the second light-emitting element 320 of the first-first subpixel to the first-third subpixels SP11, SP12, SP13 may always be turned on regardless of the modes. Since the first viewing angle lens 510 is disposed on the light-emitting elements of the first-first subpixel to the first-third subpixel SP11, SP12, and SP13, the image output from the first-first subpixel to the first-third subpixel SP11, SP12, and SP13 may have a wide viewing angle. Since the light-emitting elements disposed in the first display area DA1 all emit light regardless of the first mode and the second mode, the display efficiency of the display device may be improved by the light-emitting elements disposed in the first display area DA1.

In the second display area DA2, only the first light-emitting elements 310 may be turned on in the first mode, and only the second light-emitting elements 320 may be turned on in the second mode, which is the viewing angle control mode. In order to implement the first and second modes, both the first viewing angle lenses 510 and the second viewing angle lenses 520 may be disposed on the second pixel PIX2. In contrast, only the first viewing angle lenses 510 may be disposed on the first pixel PIX1 where there is no mode change.

Accordingly, the number of first viewing angle lenses 510 in the second display area DA2 may be less than the number of first viewing angle lenses 510 in the first display area DA1. In such a configuration, the shape and area of the lenses disposed in the first display area DA1 and the second display area DA2 may be different, resulting in different reflectivity from the lenses. Therefore, there is a problem that the boundary between the first display area DA1 and the second display area DA2 may be observed from the outside. In particular, as there is no image output when the display device is turned off, the boundary may be more easily perceived by differences in the reflection properties of the lenses.

The first dummy lenses 530 provided in the first display area DA1 may be disposed in an empty area in the first display area DA1 in which none of the first-first to the first-third subpixels SP11, SP12, and SP13 are disposed. The shape of the first dummy lenses 530 may correspond to the shape of the second viewing angle lenses 520.

The second dummy lenses 540 provided in the second display area DA2 may be disposed in an empty area in the second display area DA2 in which none of the second-first to the second-third subpixels SP21, SP22, and SP23 are disposed. The shape of the second dummy lenses 540 may correspond to the shape of the first viewing angle lenses 510.

The first dummy lenses 530 and the second dummy lenses 540 may be disposed in areas corresponding to each other. For example, the location at which the first dummy lenses 530 is disposed within the first pixel PIX1 may be the same as the location at which the second dummy lenses 540 is disposed within the second pixel PIX2.

According to the embodiment, the total areas of the lenses in the first display area DA1 and the second display area DA2 are made the same by means of the dummy lenses, which can improve the problem of visually perceiving the boundary between the first display area DA1 and the second display area DA2.

The sum of the areas of the first viewing angle lenses 510 and the first dummy lenses 530 in the first pixel PIX1 may be equal to the sum of the areas of the first viewing angle lenses 510, the second viewing angle lenses 520, and the second dummy lenses 540 in the second pixel PIX2. For example, the area of the first viewing angle lens 510 may be twice the area of the second viewing angle lens 520. The shape of the first dummy lens 530 may be the same as the shape of the second viewing angle lens 520, and the shape of the second dummy lens 540 may be the same as the shape of the first viewing angle lens 510.

For example, the number of the first viewing angle lenses 510 disposed on the first pixel PIX1 may be six, and the number of the first dummy lenses 530 may be five. If the area of the first viewing angle lens 510 is calculated as 1 point and the area of the second viewing angle lens 520 is calculated as 0.5 points, the total area of the lenses disposed in the first pixel PIX1 may be 8.5 (=(6×1)+(5×0.5)).

The number of the first viewing angle lenses 510 disposed in the second pixel PIX2 may be three, the number of the second viewing angle lenses 520 may be five, and the number of the second dummy lenses 540 having the same area as the first viewing angle lens 510 may be three. Therefore, the total area of the lenses disposed in the second pixel PIX2 may be 8.5 (=(3×1)+(5×0.5)+(3×1)).

Accordingly, since the first pixel PIX1 and the second pixel PIX2 have the same total lens area, they may have similar reflection properties. Thus, the difference in the reflection properties at the boundary between the first pixel PIX1 and the second pixel PIX2 may be improved.

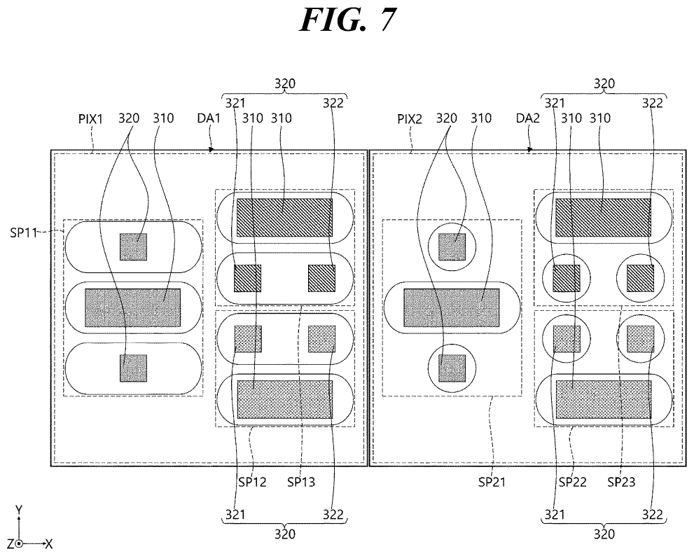

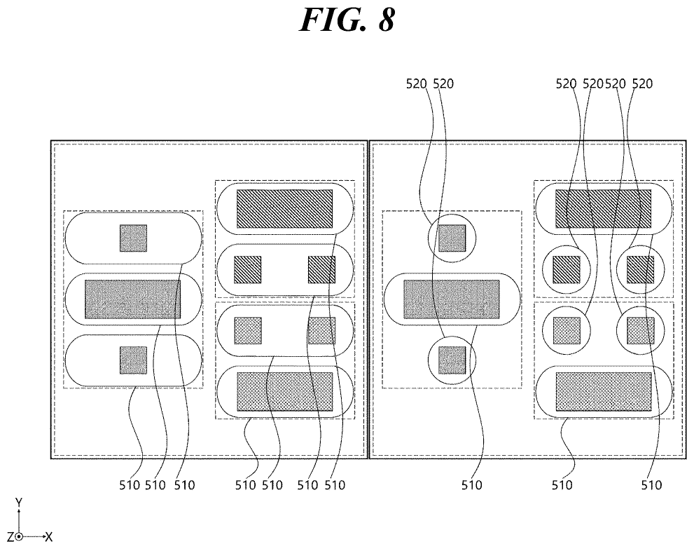

FIGS. 7 to 8 are diagrams illustrating pixels arranged in a first display area and a second display area of a display panel according to a second embodiment of the present specification. FIGS. 7 and 8 use different reference numerals to illustrate their respective configurations. For example, FIG. 8 refers to various lenses that are not referenced in FIG. 7. Further, there is a difference in the location of the subpixels and/or the number of light-emitting elements included in the subpixels from the first embodiment described above. The same or similar reference numerals are given to the components that function substantially the same as or similar to the embodiments described above, and descriptions thereof are omitted.

Referring to FIGS. 7 and 8, a plurality of first pixels PIX1 may include a first-first subpixel SP11 that outputs red light, a first-second subpixel SP12 that outputs green light, and a first-third subpixel SP13 that outputs blue light.

Each of the first-first to the first-third subpixels SP11, SP12, and SP13 may include a first light-emitting element 310 and a second light-emitting element 320. The light-emitting elements in the first-first to the first-third subpixels SP11, SP12, and SP13 may output different colors of light. For example, the first light-emitting element 310 and the second light-emitting element 320 of the first-first subpixel SP11 may emit red light, the first light-emitting element 310 and the second light-emitting element 320 of the first-second subpixel SP12 may emit green light, and the first light-emitting element 310 and the second light-emitting element 320 of the first-third subpixel SP13 may emit blue light.

In the embodiment, the second light-emitting element 320 of the first-first subpixel SP11 may be provided in plurality. For example, the number of the second light-emitting element 320 of the first-first subpixel SP11 may be two.

The plurality of second pixels PIX2 disposed in the display area DA2 may include a second-first subpixel SP21 that emits red light, a second-second subpixel SP22 that emits green light, and a second-third subpixel SP23 that emits blue light.

The second-first subpixel to the second-third subpixel SP21, SP22, and SP23 may include the first light-emitting element 310 and the second light-emitting element 320 that may be selectively driven. The first light-emitting element 310 and the second light-emitting element 320 of the second-first subpixel SP21 may emit red light, the first light-emitting element 310 and the second light-emitting element 320 of the second-second subpixel SP22 may emit green light, and the first light-emitting element 310 and the second light-emitting element 320 of the second-third subpixel SP23 may emit blue light.

The first light-emitting elements 310 and the second light-emitting element 320 of the second-first subpixel to the second-third subpixel SP21, SP22, and SP23 may be selectively driven according to the modes. As an example, in the first mode, only the first light-emitting element 310 may be turned on. As a result, the image output from the second display area DA2 may be visually perceived at a relatively wide angle. However, in the second mode of controlling the viewing angle, only the second light-emitting element 320 is turned on, so that the image output from the second display area DA2 may only be visually perceived at a relatively narrow angle.

According to an embodiment, in the first display area DA1, the first light-emitting element 310 and the second light-emitting element 320 of the first-first subpixel to the first-third subpixels SP11, SP12, SP13 may always be turned on regardless of the modes. Since the first viewing angle lens 510 is disposed on the light-emitting elements of the first-first subpixel to the first-third subpixel SP11, SP12, and SP13, the image output from the first-first subpixel to the first-third subpixel SP11, SP12, and SP13 may have a wide viewing angle. Since the light-emitting elements disposed in the first display area DA1 all emit light regardless of the first mode and the second mode, the display efficiency of the display device may be improved by the light-emitting elements disposed in the first display area DA1.

Accordingly, the number of first viewing angle lenses 510 in the second display area DA2 may be less than the number of first viewing angle lenses 510 in the first display area DA1. In such a configuration, the shape and area of the lenses disposed in the first display area DA1 and the second display area DA2 may be different, resulting in different reflectivity from the lenses. Therefore, there is a problem that the boundary between the first display area DA1 and the second display area DA2 may be observed from the outside. In particular, as there is no image output when the display device is turned off, the boundary may be more easily perceived by differences in the reflection properties of the lenses.

In order to solve the problem of perceived visibility at the boundary due to the difference in reflection properties, the pixel arrangement of the display panel according to the second embodiment of the present specification may further include a third display area according to the first to third modified examples, as described hereinafter. The third display area may vary in light-emitting area per unit pixel as it goes further in a first direction (e.g., X-axis direction) from the first display area toward the second display area.

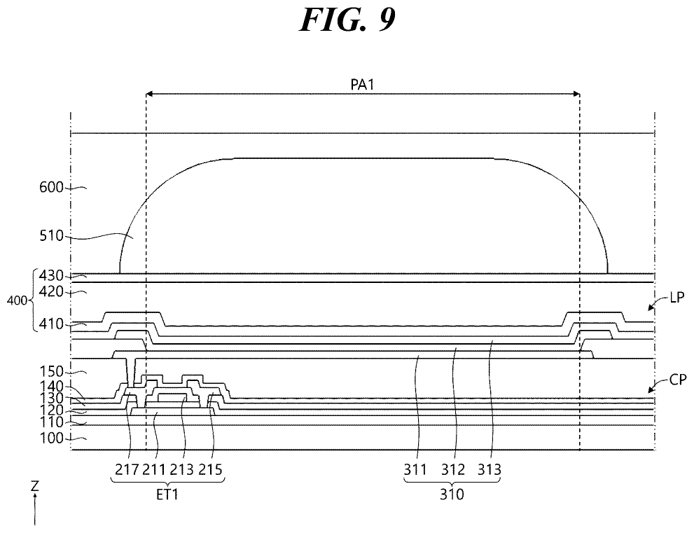

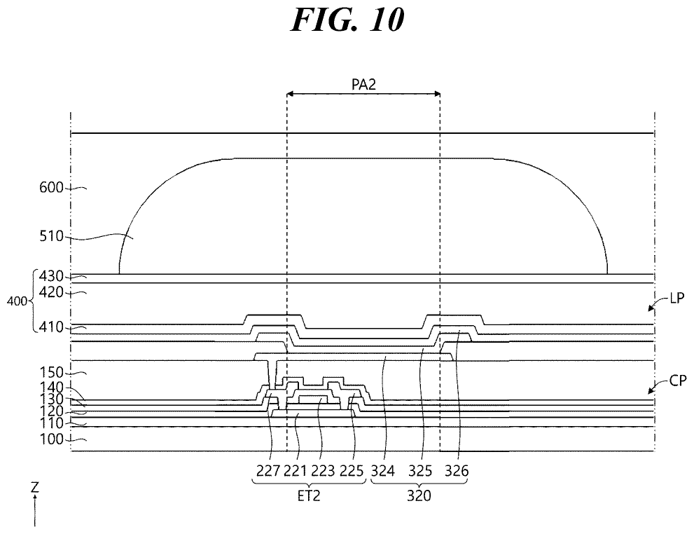

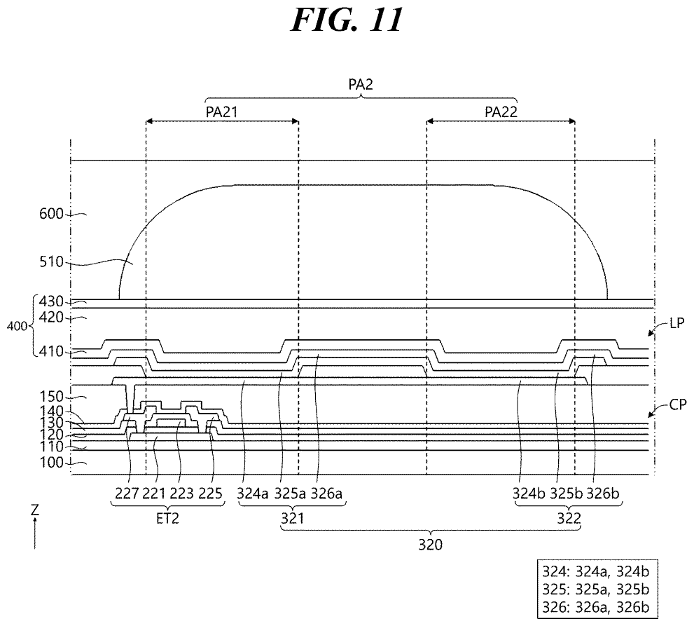

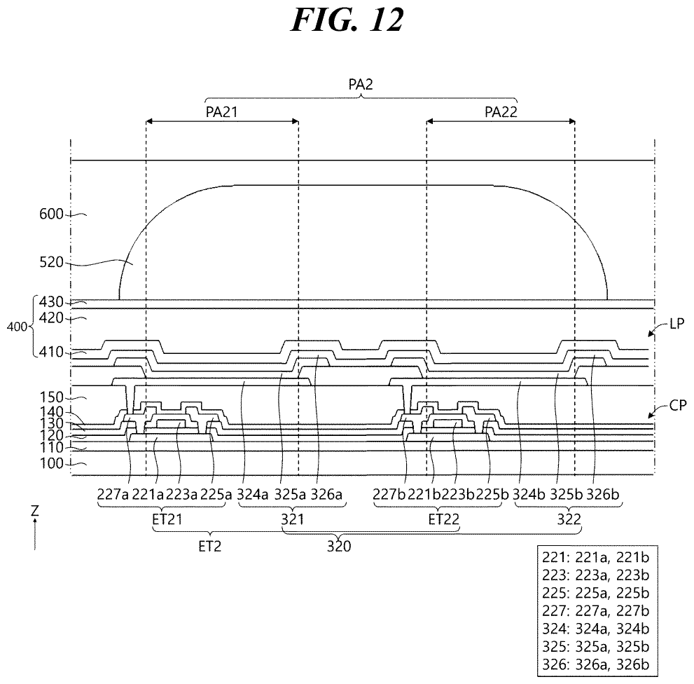

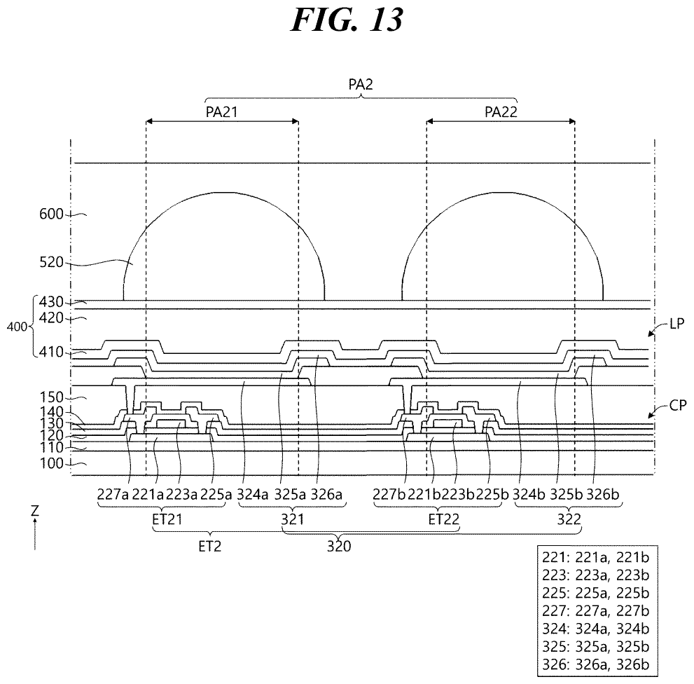

FIG. 9 is a cross-sectional view of a display panel according to an embodiment of the present specification. FIG. 10 is a cross-sectional view of a display panel according to an embodiment of the present specification. FIG. 11 is a cross-sectional view of a display panel according to an embodiment of the present specification; FIG. 12 is a cross-sectional view of a display panel according to an embodiment of the present specification. FIG. 13 is a cross-sectional view of a display panel according to an embodiment of the present specification.

Referring to FIGS. 9 to 13, the emission control transistors ET1 and ET2 may be electrically connected to the first or second electrodes of the driving transistor. The emission control transistors ET1 and ET2 may be electrically connected between the first and second lower electrodes 311 and 324 of the light-emitting elements 310 and 320. The emission control transistors ET1 and ET2 may include semiconductor patterns 211 and 221, gate electrodes 213 and 223, source electrodes 215 and 225, and first drain electrodes 217 and 227.

A circuit layer CP, an emission layer LP, and a viewing angle lens 510 and 520 may be disposed on the substrate 100. The first viewing angle lens 510 may be formed to have a flat surface in an area facing the light-emitting area PA1 of the first light-emitting element 310. Alternatively, the first viewing angle lens 510 may be formed to have a flat surface in an area facing the light-emitting area PA2 of the second light-emitting element 320. Therefore, the light emitted by the light-emitting elements 310 and 320 is not condensed when it passes through the viewing angle lenses 510 and 520, resulting in a wide viewing angle.

The second viewing angle lens 520 may be formed to have a flat surface in an area facing the light-emitting area PA2 of the second light-emitting element 320. Therefore, the light emitted by the second light-emitting element 320 may be condensed when it passes through the second viewing angle lens 520, resulting in a reduced viewing angle.

A device buffer film 110, a gate insulating film 120, an interlayer insulating film 130, a lower protective film 140 and an overcoat layer 150 may be stacked on the substrate 100.

The device buffer film 110 may include an insulating material. For example, the device buffer film 110 may include inorganic insulating materials such as silicon oxide (SiO) and silicon nitride (SiN). The device buffer film 110 may have a multi-layer structure. For example, the device buffer film 110 may have a stacked structure of a film made of silicon nitride (SiN) and a film made of silicon oxide (SiO).

The gate insulating film 120 may include an insulating material. For example, the gate insulating film 120 may include inorganic insulating materials such as silicon oxide (SiO) and silicon nitride (SiN). The gate insulating film 120 may include a material having a high dielectric constant.

The interlayer insulation film 130 and the lower protective film 140 may include an insulating material. For example, the interlayer insulating film 130 may include inorganic insulating materials such as silicon oxide (SiO) and silicon nitride (SiN).

The overcoat layer 150 may include an organic material. The overcoat layer 150 may include a different material than the lower protective film 140. For example, the overcoat layer 150 may include an organic material.

An encapsulation member 400 may prevent damage to the light-emitting elements 310 and 320 from external moisture and impact. The encapsulation member 400 may have a multi-layer structure. For example, the encapsulation member 400 may include a first encapsulation layer 410, a second encapsulation layer 420, and a third encapsulation layer 430 stacked in order.

Referring to FIG. 9, the first light-emitting element 310 according to an embodiment may have a relatively large light-emitting area PA1. A first relatively wide viewing angle lens 510 may be disposed on the first light-emitting element 310. The first light-emitting element 310 may be connected to the first emission control transistor ET1 and may be emitted light by a driving voltage supplied from it. The light-emitting element in this embodiment may correspond to the first light-emitting element 310 of the first-first subpixel SP11, the first light-emitting element 310 of the first-second subpixel SP12, the first light-emitting element 310 of the first-third subpixels SP13, the first light-emitting element 310 of the second-first subpixel SP21, the first light-emitting element 310 of the second-second subpixel SP22, or the first light-emitting element 310 of the second-third subpixels SP23 in the first embodiment described above and/or the second embodiment described above.

Referring to FIG. 10, the second light-emitting element 320 according to an embodiment may have a relatively narrow light-emitting area PA2. A first relatively wide viewing angle lens 510 may be disposed on the second light-emitting element 320. The second light-emitting element 320 may be connected to the second emission control transistor ET2 and may be emitted light by a driving voltage supplied from it. The light-emitting element in this embodiment may correspond to the second light-emitting element 320 of the first-first subpixel SP11 in the first embodiment described above. Alternatively, it may correspond to the second light-emitting element 320 of the first-first subpixel SP11 in the second embodiment described above.

Referring to FIG. 11, the second light-emitting element 320 according to an embodiment may have a relatively narrow light-emitting areas PA21 and PA22. The second light-emitting element 320 may include a second-first light-emitting element 321 and a second-second light-emitting element 322. A first relatively wide viewing angle lens 510 may be disposed on the second light-emitting element 320. The second light-emitting element 320 may be connected to the second emission control transistor ET2 and may be emitted light by a driving voltage supplied from it. Accordingly, the second-first light-emitting element 321 and the second-second light-emitting element 322 may be turned on simultaneously or turned off simultaneously, according to the modes. The light-emitting element in this embodiment may correspond to the second light-emitting element 320 of the first-second subpixels SP12 or the second light-emitting element 320 of the first-third subpixels SP13 in the first embodiment described above. Alternatively, it may correspond to the second light-emitting element 320 of the first-second subpixels SP12 or the second light-emitting element 320 of the first-third subpixels SP13 in the second embodiment described above.

Referring to FIGS. 12 and 13, the first light-emitting element 310 according to an embodiment may have a relatively narrow light-emitting area PA2. A first relatively wide viewing angle lens 510 may be disposed on the first light-emitting element 310. The first light-emitting element 310 may be connected to the first emission control transistor ET1 and may be emitted light by a driving voltage supplied from it. Accordingly, the second-first light-emitting element 321 and the second-second light-emitting element 322 may be selectively turned on/turned off, according to the modes. The light-emitting element in this embodiment may correspond to the second light-emitting element 320 of the second-second subpixel SP22 or the second light-emitting element 320 of the second-third subpixel SP23 in the first embodiment described above. Alternatively, it may correspond to the second light-emitting element 320 of the second-second subpixels SP22 or the second light-emitting element 320 of the second-third subpixels SP23 in the second embodiment described above. Alternatively, it may correspond to the second light-emitting element 320 in the third display area DA3 in the first modified example or the third modified example of the second embodiment to be described later.

A person of ordinary skill in the art may readily derive cross-sectional views of the subpixels disposed in the first to third display areas disclosed herein by reference to and in combination with the cross-sectional views according to the embodiments described above.

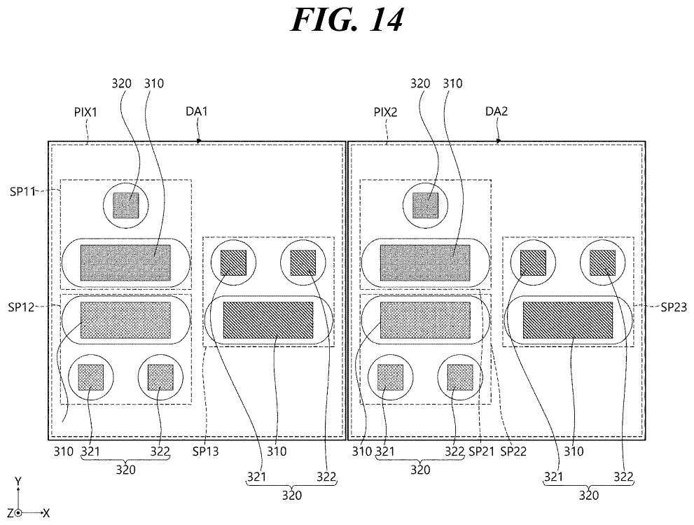

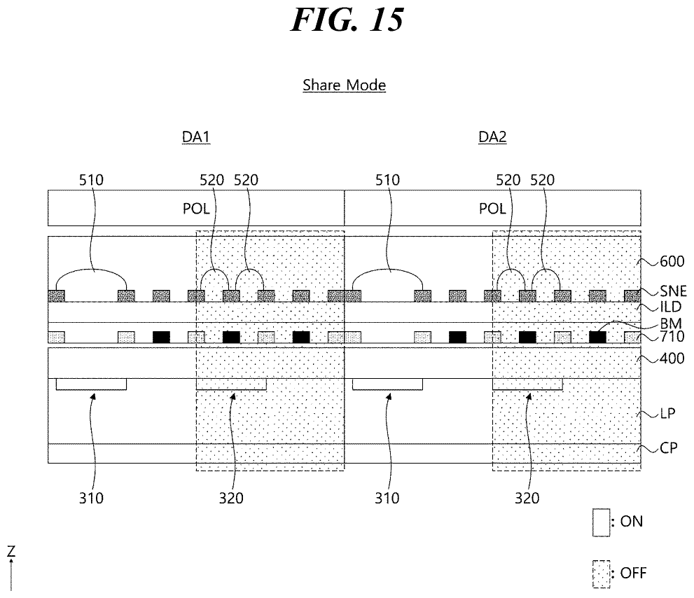

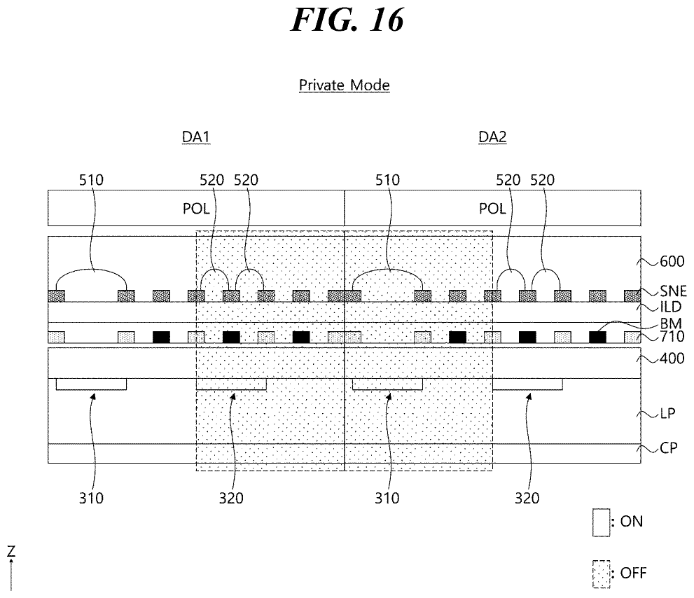

FIG. 14 is a diagram illustrating a display device in which viewing angle lenses having the same shape are disposed in the first display area and the second display area. FIG. 15 is a diagram illustrating a state in which the display device of FIG. 14 is driven in a first mode. FIG. 16 is a diagram illustrating a state in which the display device of FIG. 15 is driven in a second mode.

Referring to FIG. 14, the first pixel PIX1 disposed in the first display area DA1 may include the first-first subpixel to the first-third subpixel SP11, SP12, and SP13. The first viewing angle lens 510 may be disposed on the first light-emitting element 310 of the first-first to the first-third subpixel SP11, SP12, and SP13, and the second viewing angle lens 520 may be disposed on the second light-emitting element 320 of the first-first to the first-third subpixel SP11, SP12, and SP13.

The second pixel PIX2 disposed in the second display area DA2 may include the second-first subpixel to the second-third subpixel SP21, SP22, and SP23. The first viewing angle lens 510 may be disposed on the first light-emitting element 310 of the second-first subpixel to the second-third subpixel SP21, SP22, and SP23, and the second viewing angle lens 520 may be disposed on the second light-emitting element 320 of the second-first subpixel to the second-third subpixel SP21, SP22, and SP23.

According to this embodiment, the first viewing angle lens 510 may be disposed on both the first light-emitting elements 310 in the first display area DA1 and the second display area DA2, and the second viewing angle lens 520 may be disposed on both the second light-emitting elements 320 in the first display area DA1 and the second display area DA2. Accordingly, the first viewing angle lens and second viewing angle lens arranged in the first display area DA1 may have the same number and shape as the first viewing angle lens and the second viewing angle lens arranged in the second display area DA2. Therefore, the boundary between the first display area DA1 and the second display area DA2 may not be visually perceived due to similar reflection properties.

Referring to FIG. 15, when operating in the first mode, in both the first display area DA1 and the second display area DA2, the first light-emitting element 310 may be turned on and the second light-emitting element 320 may be turned off.

Referring to FIG. 16, when operating in the second mode, the second light-emitting element 320 may be turned on in the second display area DA2, whereas the first light-emitting element 310 may be turned on in the first display area DA1. Therefore, in the first display area DA1, which is not selectively driven, the second light-emitting element 320 is always off, which has a disadvantage in terms of luminance, lifetime, or efficiency.

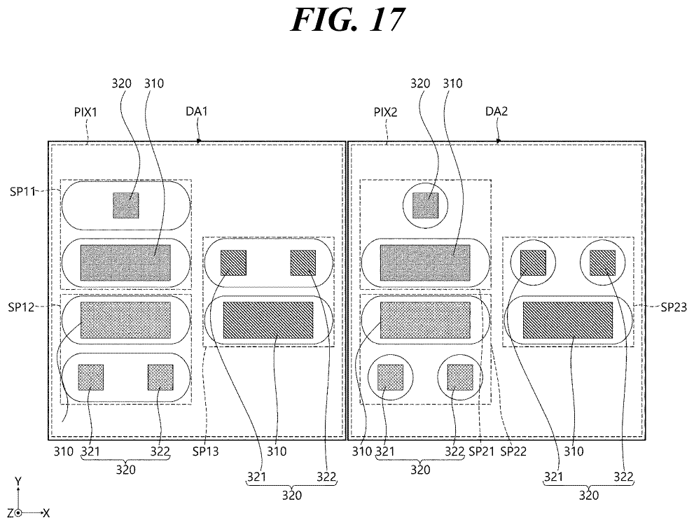

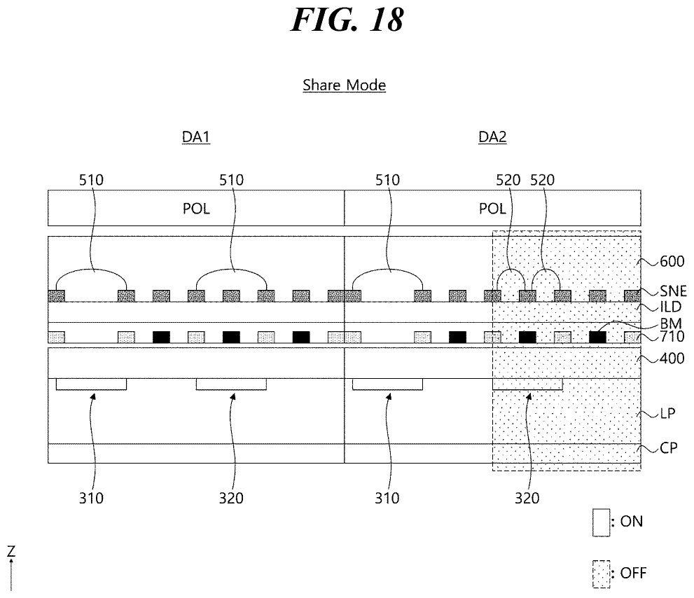

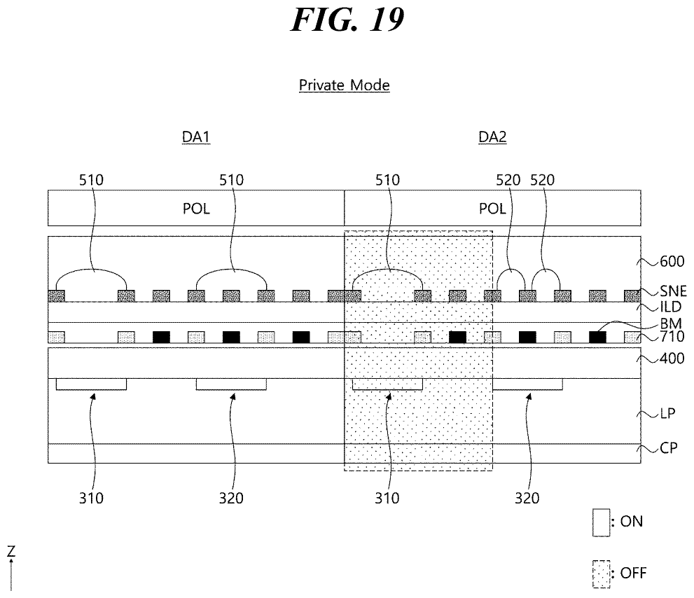

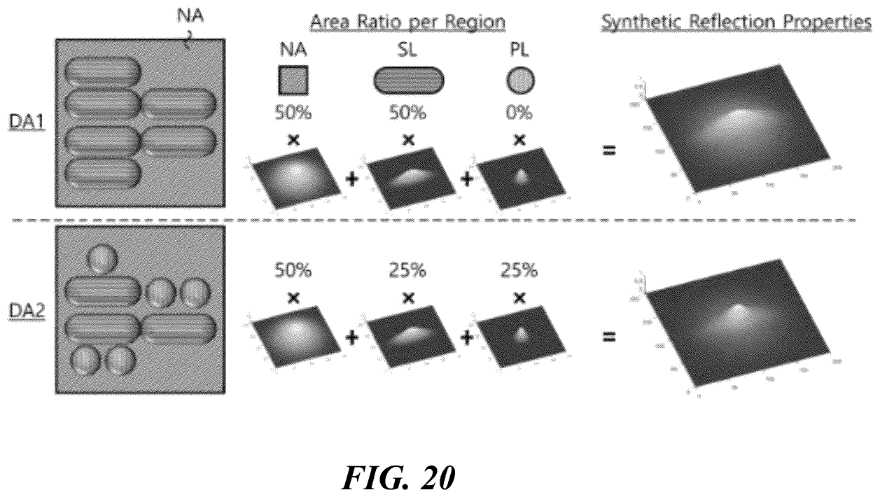

FIG. 17 is a diagram illustrating a display device in which viewing angle lenses having different shapes are disposed in the first display area and the second display area. FIG. 18 is a diagram illustrating a state in which the display device of FIG. 17 is driven in a first mode. FIG. 19 is a diagram illustrating a state in which the display device of FIG. 17 is driven in a second mode. FIG. 20 is a diagram illustrating that reflection properties of a first display area and a second display area are different from each other in the display device of FIG. 17.

Referring to FIG. 17, the first pixel PIX1 disposed in the first display area DA1 may have the first viewing angle lens 510 disposed on both the first light-emitting element 310 and the second light-emitting element 320 of the first-first subpixel to the first-third subpixel SP11, SP12, and SP13.

The second pixel PIX2 disposed in the second display area DA2 may have the first viewing angle lens 510 disposed on the first light-emitting element 310 of the second-first subpixel to the second-third subpixel SP21, SP22, and SP23, and the second viewing angle lens 520 disposed on the second light-emitting element 320 of the second-first subpixel to the second-third subpixel SP21, SP22, and SP23.

Referring to FIG. 18, when operating in the first mode, both the first light-emitting element 310 and the second light-emitting element 320 in the first display area DA1 may emit light, and the first light-emitting element 310 in the second display area DA2 may emit light.

Referring to FIG. 19, when operating in the second mode, both the first light-emitting element 310 and the second light-emitting element 320 in the first display area DA1 may emit light, and the second light-emitting element 320 in the second display area DA2 may emit light.

According to the embodiment, the first light-emitting element 310 and the second light-emitting element 320 always drive in the first display area DA1 regardless of the modes, whereas the first light-emitting element 310 and the second light-emitting element 320 may selectively drive in the second display area DA2 according to the modes. Accordingly, the efficiency of the light-emitting elements disposed in the first display area DA1 may be improved.

Referring to FIG. 20, the reflection properties in the area at which no lens is disposed may be different from the reflection properties of the wide viewing angle lens SL and the narrow viewing angle lens PL. Therefore, the synthetic reflection properties in the first pixel PIX1 may differ from the synthetic reflection properties in the second pixel PIX2. This is due to the fact that the first pixel, PIX1, and the second pixel, PIX2, have different areas occupied by the SL wide angle lens and the PL narrow angle lens in these pixels. As a result, there is the problem that the boundary between the first display area DA1 and the second display area DA2 is perceived visually.

If the lenses are formed to have the same shape in both the first display area DA1 and the second display area DA2, as shown in the structure in FIG. 14, the problem of visible boundaries may be improved, but there are problems in terms of luminance and lifetime because only some of the light-emitting elements are used in the first display area DA1.

As shown in the structure of FIG. 17, if the shapes of the lenses in the first display area DA1 and the second display area DA2 are different, all of the light-emitting elements may be used in the first display area DA1, which is advantageous in terms of luminance and lifetime, but there is a problem in that the boundary between the first display area DA1 and the second display area DA2 is still visible due to the changes in pixel densities, etc.

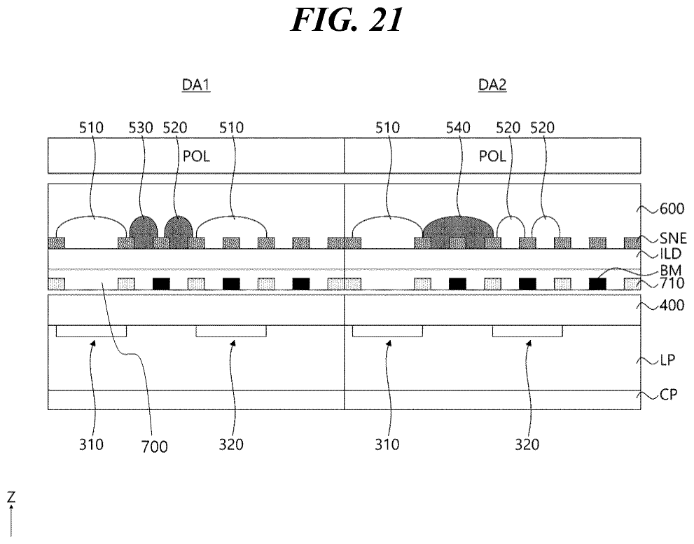

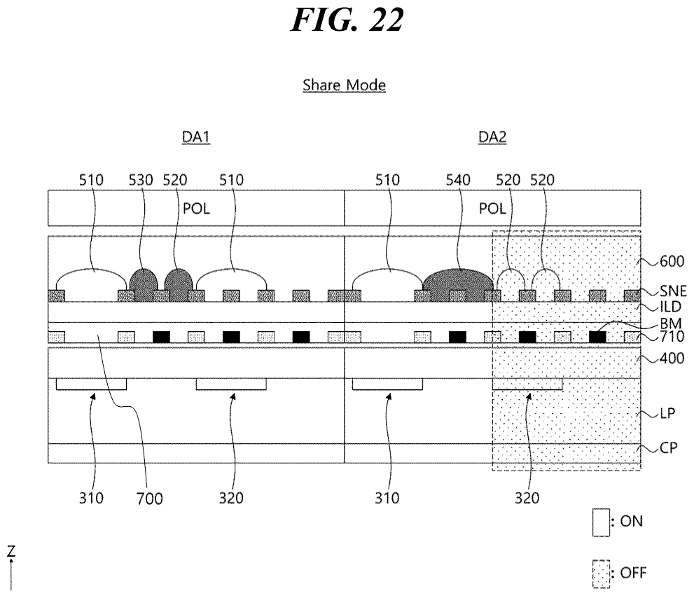

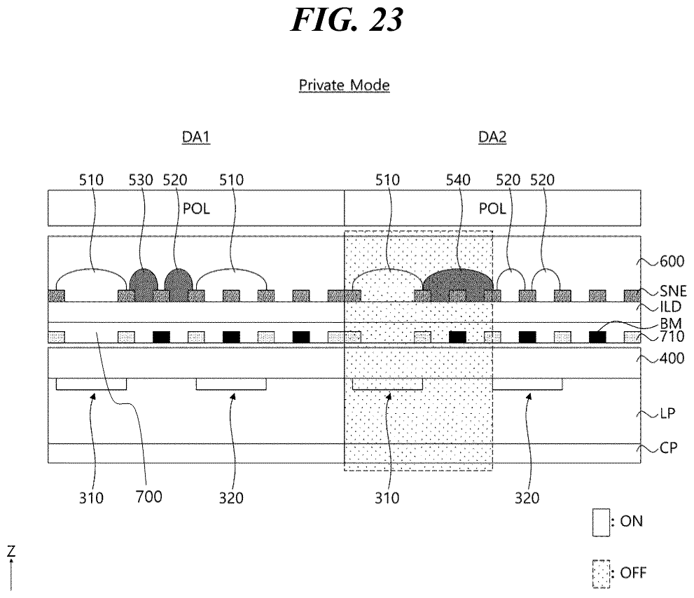

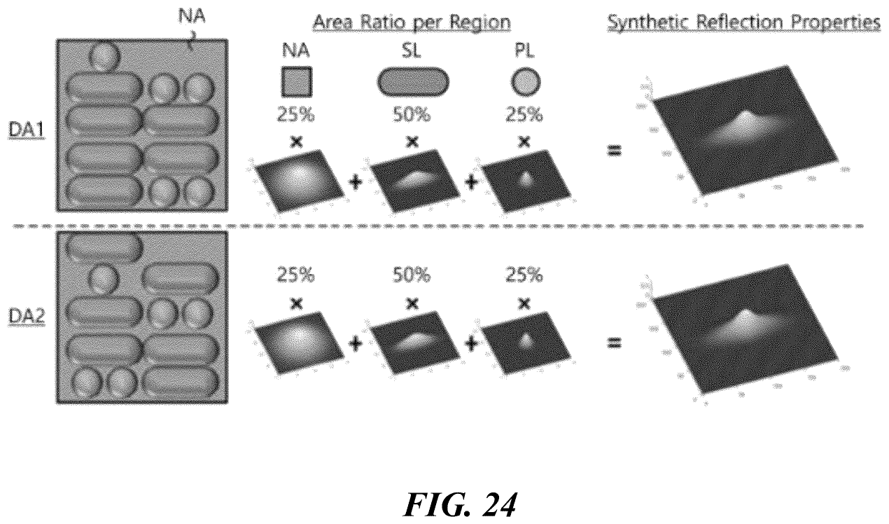

FIG. 21 is a diagram illustrating a display device according to an embodiment of the present specification. FIG. 22 is a diagram illustrating a state in which the display device of FIG. 21 is driven in a first mode. FIG. 23 is a diagram illustrating a state in which the display device of FIG. 21 is driven in a second mode. FIG. 24 is a diagram illustrating that reflection properties of a first display area and a second display area are similar to each other in the display device according to the embodiment of the present specification.

Referring to FIG. 5 and FIGS. 21 to 23, when the display device according to the embodiment operates in the first mode, the first display area DA 1 may allow both the first light-emitting element 310 and the second light-emitting element 320 to emit light, and the second display area DA 2 may allow only the first light-emitting element 310 to emit light.

When operating in the second mode, the first display area DA1 may allow both the first light-emitting element 310 and the second light-emitting element 320 to emit light, and the second display area DA 2 may allow only the second light-emitting element 320 to emit light.

The display device may further include a touch layer 700 including a touch sensor on the light-emitting layer LP. The touch sensor may detect the touch of a user and/or a tool. The display device of the embodiment may be a touch display device that executes a specific program or applies a specific signal by the touch of a user and/or a tool. The touch sensor may detect the touch of a user and/or tool through changes in mutual capacitance. The touch sensor may include a plurality of touch electrodes 710. A polarizer POL may be disposed on top of the encapsulation member 600.

Referring to FIG. 24, in the display device according to an embodiment, a first pixel PIX1 and a second pixel PIX2 have an equal 25% area NA in which no lens is formed, an equal 50% area in which a wide viewing angle lens SL is formed, and an equal 25% area in which a narrow viewing angle lens PL is disposed. Therefore, the areas occupied by the lenses in the first pixel PIX1 and the second pixel PIX2 are the same, so that the synthetic reflection properties may be substantially the same. As a result, the boundary between the first display area DA1 and the second display area DA2 may not be visible. Here, the term of the wide viewing angle lens SL may be a term including the first viewing angle lens 510 and the second dummy lens 540, and the term of the narrow viewing angle lens PL may be a term including the second viewing angle lens 520 and the first dummy lens 530.

According to an embodiment, the use of all the light-emitting elements in the first display area DA1 enables low power operation and at the same time improves the problem that the boundary between the first display area DA1 and the second display area DA2 is visible.

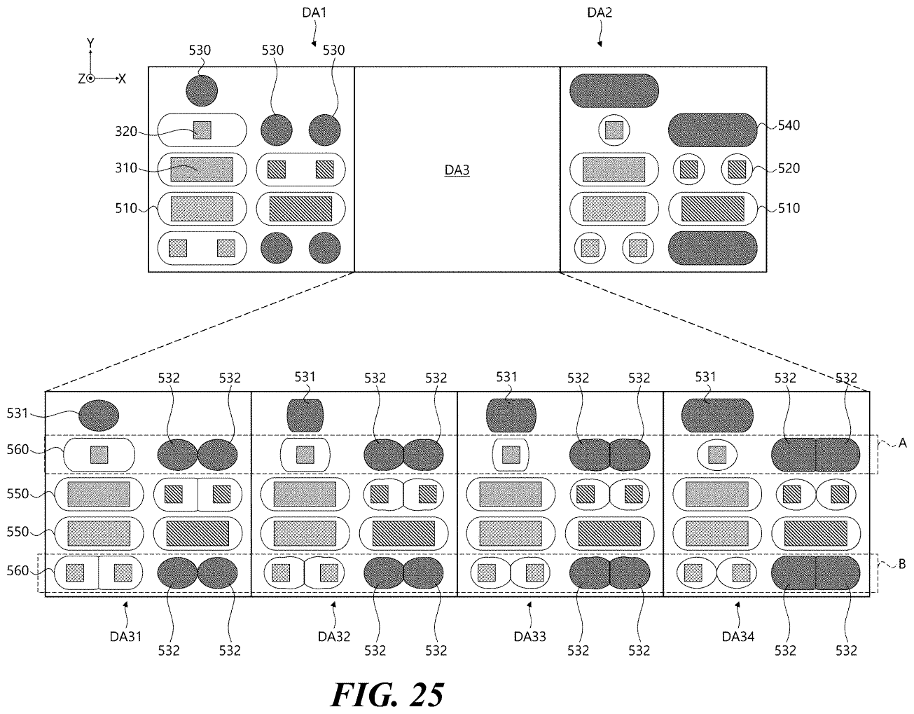

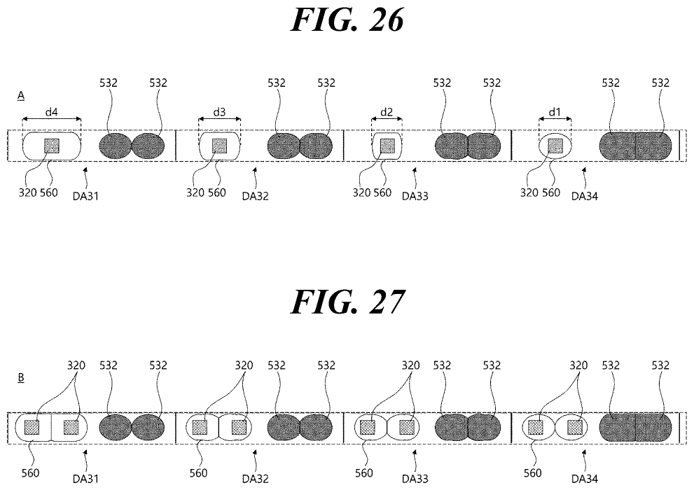

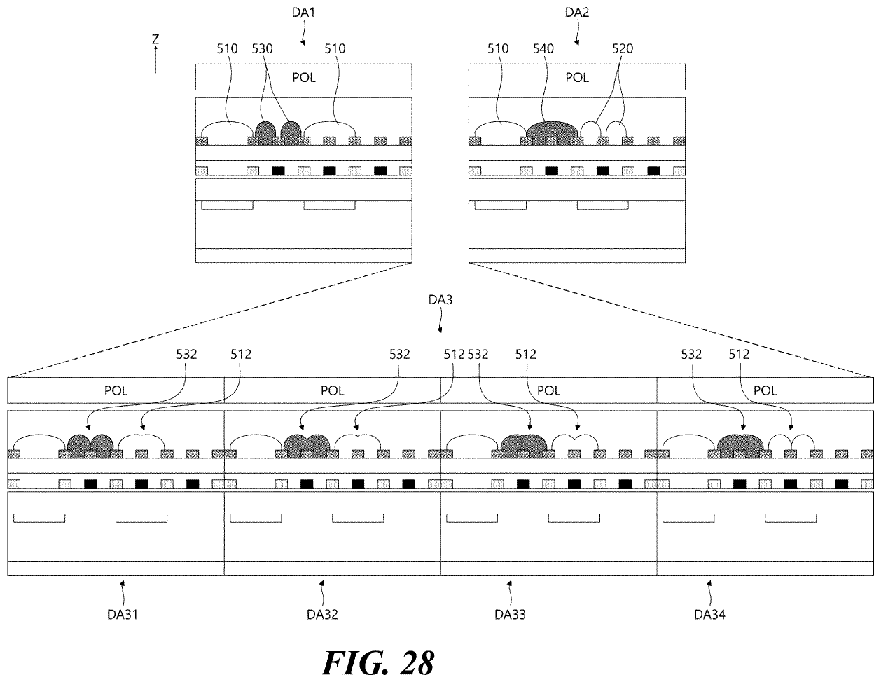

FIG. 25 is a diagram illustrating a first modified example of the display panel according to the first embodiment of the present specification. FIG. 26 is a partial enlarged view of a portion A of FIG. 25; FIG. 27 is a partial enlarged view of a portion B of FIG. 25; FIG. 28 is a diagram illustrating a display panel according to a first modified example.

Referring to FIG. 25, the display panel may include a third display area DA3 between the first display area DA1 and the second display area DA2. In the first pixel PIX1 of the first display area DA1, the first viewing angle lens 510 may be disposed on the first light-emitting element 310 and the second light-emitting element 320, and a first dummy lens 530 may be disposed at a position that does not overlap the first light-emitting element 310 and the second light-emitting element 320.

In the second pixel PIX2 of the second display area DA2, the first viewing angle lens 510 may be disposed on the first light-emitting element 310 and the second viewing angle lens 520 may be disposed on the second light-emitting element 320. In addition, in the second pixel PIX2, a second dummy lens 540 may be disposed in a position that does not overlap the first light-emitting element 310 and the second light-emitting element 320. The structures of the first display area DA1 and the second display area DA2 may be as described in all the above discussions of FIGS. 5 and 6.

The third display area DA3 may include a third viewing angle lens 550 disposed on the first light-emitting element 310, a fourth viewing angle lens 560 disposed on the second light-emitting element 320, and third dummy lenses 531 and 532 disposed in non-overlapping positions with the first light-emitting element 310 and the second light-emitting element 320.

The shapes of the third dummy lenses 531 and 532 may vary in the first direction. The first direction may be the direction (the X-axis direction) from the first display area DA1 toward the second display area DA2.

The third display area DA3 may include third-first to third-fourth display areas DA31, DA32, DA33, and DA34 disposed in the first direction. The shapes of the third dummy lenses 531 and 532 may change from the shape of the second viewing angle lens 520 to the shape of the first viewing angle lens 510 progressively from the third-first display area DA31 to the third-fourth display area DA34.

For example, in the case of the pixel having first to fifth rows spaced apart in the Y-axis direction, one third-first dummy lens 531 disposed in the first row may gradually increase in width as it goes further in the first direction. In addition, the two third-second dummy lenses 532 disposed in the second row and the fifth row may gradually change into one lens in the first direction. Therefore, the third dummy lenses 531 and 532 may gradually change in shape similar to the second dummy lens 540 as they goes further in the first direction.

According to this configuration, the shapes of the lenses in the third display area DA3, located between the first display area DA1 and the second display area DA2, gradually change, minimizing the perceived heterogeneity at the boundary. In this case, the areas of the lens in the first display area to the third display area DA1, DA2, and DA3 may all be the same.

Referring to FIGS. 25 and 26, the shapes of the viewing angle lenses together with the dummy lens in the third display area DA3 may also change progressively in the first direction. The third-second dummy lens 532 in the third-first display area DA31 located closest to the first display area DA1 may have a shape similar to the first dummy lens 530 in the first display area DA1, but its shape may be gradually transformed into the shape of the second dummy lens 540 in the second display area DA2 as it goes further in the first direction.

In addition, the fourth viewing angle lens 560 in the third-first display area DA31 may have a first width d4, while its width may gradually decrease in the first direction (d4>d3>d3>d1). According to this configuration, the shape of the fourth viewing angle lens 560 in the third-first display area DA31 may be gradually transformed from the shape of the first viewing angle lens 510 disposed in the first display area DA1 to the shape of the second viewing angle lens 520 disposed in the second display area DA2, thereby reducing the difference in reflection properties. In contrast, the third viewing angle lens 550 in the third-first display area DA31 may maintain the same width in the first direction.

Referring to FIG. 27, the third-second dummy lens 532 in the third-first display area DA31 may have a shape similar to the first dummy lens 530 in the first display area DA1, but its shape may gradually change to the shape of the second dummy lens 540 in the second display area DA2 in the first direction.

In addition, the second viewing angle lens 560 disposed on the second light-emitting element 320 in the third display area DA3 may be gradually separated into two narrow viewing angle lenses in the first direction. Therefore, one wide viewing angle lens may be disposed on the two second light-emitting elements 320 in the third display area DA31, while a narrow viewing angle lens may be disposed on each of the two second light-emitting elements 320 in the third display area DA34.

According to the embodiment, by gradually changing the shape of the viewing angle lens and/or the dummy lens in the third display area DA3 between the first display area DA1 and the second display area DA2, it is possible to minimize a perceived heterogeneity at the boundary.

According to another embodiment, only the shape of the viewing angle lens in the third display area DA3 may be changed. In this case, the dummy lens in the first to third display areas may be omitted. In other words, if the shapes of the viewing angle lenses in the third display area DA3 change continuously enough to prevent the boundary between the first and second display areas from being visible, separate dummy lenses may be omitted. However, the embodiment of the present specification is not limited to those described above.

Referring to FIG. 28, the shapes of the dummy lenses in the third display area DA3 may be gradually transformed in the first direction. A method of manufacturing such a lens is not particularly limited. For example, the dummy lens may be manufactured using a thermal reflow method. The thermal reflow method may transform the lens into a desired shape by applying lens material and then applying heat to reflow it. The reflow process may be carried out in each of the third-first display area to the third-fourth display area DA31, DA32, DA33, and DA34, but the embodiment are not limited thereto.

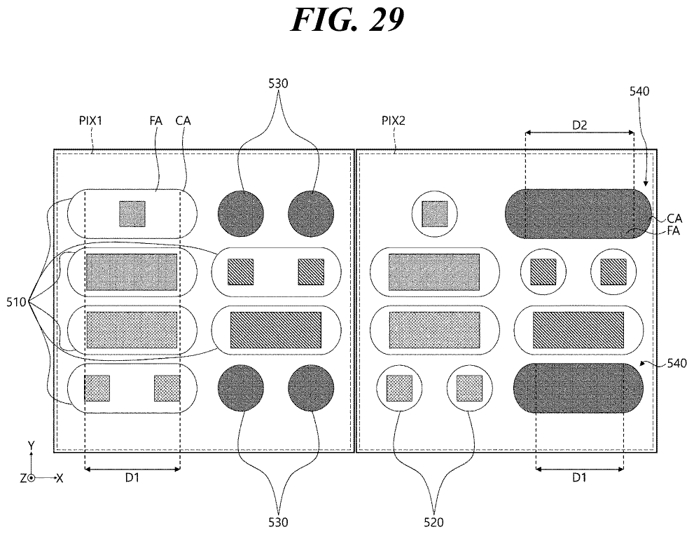

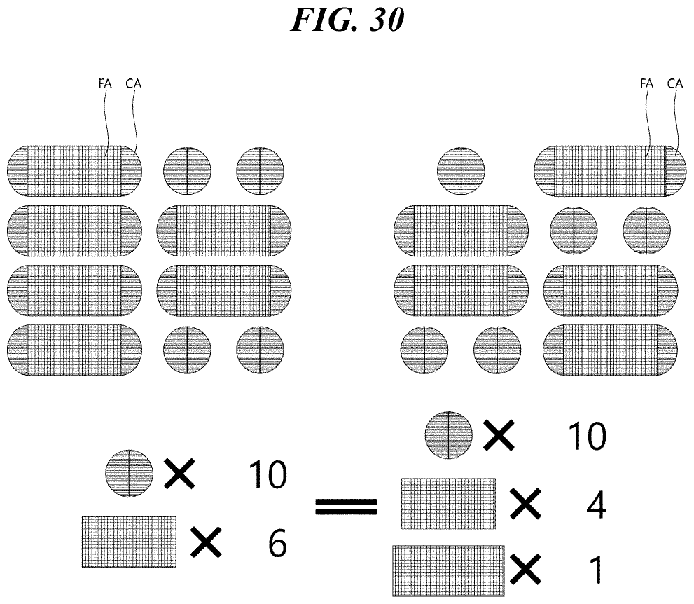

FIG. 29 is a diagram illustrating a second modified example of the display panel according to the first embodiment of the present specification. FIG. 30 is a diagram illustrating the area of viewing angle lenses disposed on the display panel according to the second modified example.

Referring to FIGS. 29 and 30, the first viewing angle lens 510 may be divided into one rectangular area FA and two semicircular areas CA. The area of two semicircular areas CA may be the same as the area of the second viewing angle lens 520 or the first dummy lens 530. If the total areas of the lenses within the pixels are the same, then similar reflection properties may be achieved even if the number and shape of the lenses are varied.

For example, the first pixel PIX1 may have six first viewing angle lenses 510 and four first dummy lenses 530. The first dummy lens 530 may have the same shape as the second viewing angle lens 520. The first viewing angle lens 510 may be divided into a rectangular area FA and two semicircular areas CA, and the first dummy lens 530 may include two semicircular areas CA. Accordingly, the lensed in the first pixel PIX1 may include 6 rectangular areas FA and 10 circular portions.

The second pixel PIX2 may have three first viewing angle lenses 510, five second viewing angle lenses 520, and two second dummy lenses 540. The first viewing angle lens 510 and the second dummy lens 540 may be divided into a rectangular area FA and a semicircular area CA, and the second viewing angle lens 520 may include two semicircular areas CA.

One of the second dummy lenses 540 may have a width D2 of the rectangular area FA that is twice the width D1 of the rectangular area of the first viewing angle lens 510. Accordingly, the second dummy lens 540 may have rectangular areas corresponding to the rectangular areas FA of the three first viewing angle lenses 510.

Accordingly, the lenses in the second pixel PIX2 may include 6 rectangular areas FA and 10 circular portions. In other words, the shapes of the lenses in the first pixel PIX1 and the shapes of the lenses in the second pixel PIX2 may be different, but the total area of the lenses may be the same. Accordingly, the reflection properties become similar in a state in which the display device is turned off, which may improve the problem of perceived visibility of the boundary between the first display area DA1 and the second display area DA2.

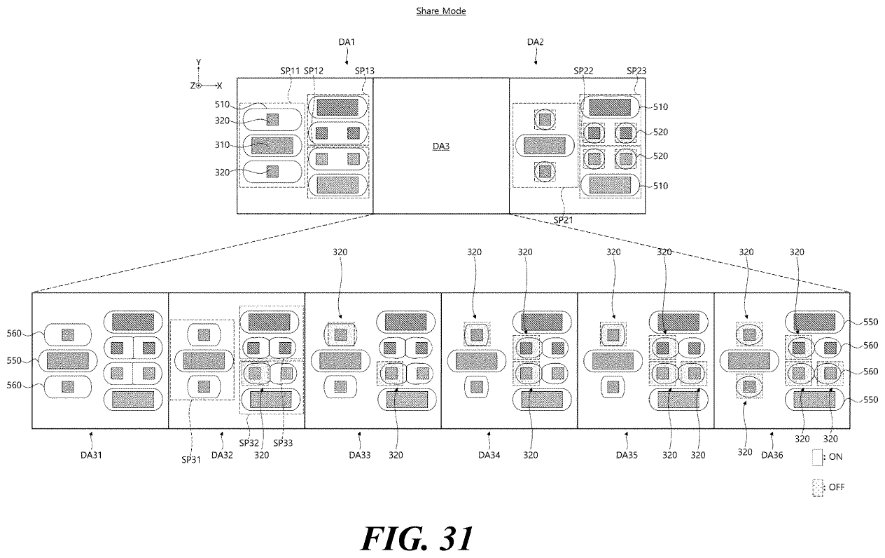

FIG. 31 is a diagram illustrating a state in which a display device including the first modified example of the display panel according to the second embodiment of the present specification is driven in a first mode.

Referring to FIG. 31, the structures of the first display area DA1 and the second display area DA2 may be as described in all the discussions of the second embodiment above. In addition, the third viewing angle lens 550 or the fourth viewing angle lens 560, etc., may also be as described in all of the above discussions.

The display panel may include a third display area DA3 disposed between the first display area DA1 and the second display area DA2. The third display area DA3 may be an area in which an emission area per unit pixel changes progressively from the first display area DA1 toward the second display area DA2 in the first mode.

In order to have a wide range of viewing angles in the first mode, all the second light-emitting elements 320 in the second display area DA2 may be in a turned off state. As described above, if the first viewing angle lens 510 is disposed on the light-emitting elements of the first display area DA1 in order to improve the luminance efficiency of the first display area DA1, a problem may occur that the boundary between the first display area DA1 and the second display area DA2 is perceived visually in the first mode. Accordingly, the display panel according to the first modified example of the second embodiment may have the third display area DA3 including a plurality of transition areas DA31, DA32, DA33, DA34, DA35, and DA36 disposed between the first display area DA1 and the second display area DA2 in order to reduce the visibility of the boundary. Each of the transition areas DA31, DA32, DA33, DA34, DA35, and DA36 according to the embodiment may gradually change in an emission area per unit pixel.

The second display area DA2 may be disposed in the first direction (e.g., in the X-axis direction) from the first display area DA1. The third display area DA3 disposed between them may include a third-first display area DA31, a third-second display area DA32, a third-third display area DA33, a third-fourth display area DA34, a third-fifth display area DA35, and a third-sixth display area DA36 arranged in the first direction. Each of the areas DA31, DA32, DA33, DA34, DA35, and DA36 may include a third pixel (a third-first pixel, a third-second pixel, a third-third pixel, a third-fourth pixel, a third-fifth pixel, and a third-sixth pixel). Each of the third pixels may include a third-first subpixel SP31, a third-second subpixel SP32, and a third-third subpixel SP33. Each of the third-first subpixel SP31, third-second subpixel SP32, and third-third subpixel SP33 may include a first light-emitting element 310 and a second light-emitting element 320.

The display panel according to the first modified example of the second embodiment may, in the first mode, adjust the emission area of the third pixel by varying the number of turned-off light-emitting elements as it proceeds further in the first direction. In one embodiment, the number of light-emitting elements disposed and turned off in the third pixel may vary progressively in the first direction. For example, the number of light-emitting elements disposed and turned off in the third pixel may increase progressively in the first direction. Accordingly, the emission area of the third pixel may decrease progressively in the first direction.

In one embodiment, the third-second pixel driven in the first mode may include a third-second subpixel SP32 that includes the turned-off second light-emitting element 320. While the embodiment illustrates turning off the second light-emitting element 320, but it is not limited thereto, the emission per pixel may be adjusted by, for example, turning off the first light-emitting element 310.

The third pixel driven in the first mode may include a third-second subpixel SP32 including the turned-off second light-emitting element 320 and a third-first subpixel SP31 including the turned-off second light-emitting element 320. The position at which the third-second subpixel SP32 including the second light-emitting element 320 turned off in the third-second pixel driven in the first mode is located may correspond to the position at which the third-second subpixel SP32 including the second light-emitting element 320 turned off in the third-third pixel driven in the first mode is located.

The third-fourth pixels driven in the first mode may include the third-second subpixel SP32 including the turned-off second light-emitting element 320, the third-first subpixel SP31 including the turned-off second light-emitting element 320, and the third-third subpixel SP33 including the turned-off second light-emitting element 320. The position at which the third-second subpixel SP32 and the third-first subpixel SP31 including the second light-emitting element 320 turned off in the third-third pixel operated in the first mode are located may correspond to the position at which the third-second subpixel SP32 and the third-first subpixel SP31 including the second light-emitting element 320 turned off in the third-third pixel operated in the first mode are located.

The third-fifth pixel driven in the first mode may include a third-second subpixel SP32 including one more turned-off second light-emitting element 320, a third-first subpixel SP31 including the turned-off second light-emitting element 320, and a third-third subpixel SP33 including the turned-off second light-emitting element 320.

The third-sixth pixel driven in the first mode may include a third-second subpixel SP32 including one more turned-off second light-emitting element 320, a third-first subpixel SP31 including one more turned-off second light-emitting element 320, and a third-third subpixel SP33 including the turned-off second light-emitting element 320.

In one embodiment, the color represented by the subpixel to be turned off may vary progressively in the first direction. The third-first subpixel SP31, the third-second subpixel SP32, and the third-third subpixel SP33 may implement any one color selected from the group consisting of red, green, and blue, respectively, without overlapping each other. For example, the colors implemented by the subpixels being turned off may be circulated in the order of green, red, and blue. In this case, the third-first subpixel SP31 may implement a red color, the third-second subpixel SP32 may implement a green color, and the third-third subpixel SP33 may implement a blue color.

The embodiment in which the sub-pixels to be turned off vary depending on the color to be implemented may be determined by considering the lifetime and/or efficiency of the light-emitting elements implementing red, green, or blue. For example, in the third pixel disposed in the third-second display area DA32, the second light-emitting element 320 disposed in the third-second subpixel SP32, which implements the green color, may be turned off, since the relative luminous efficiency increases in the order of blue, red, and green. In the third-third display area DA33, the second light-emitting element 320 disposed in the third-first subpixel SP31, which implements the red color, may additionally be turned off. In the third pixel disposed in the third-fourth display area DA34, the second light-emitting element 320 disposed in the third-third subpixel SP33, which implements the blue color, may be turned off. Accordingly, the luminous efficiency of the display device may increase, enabling low-power operation.

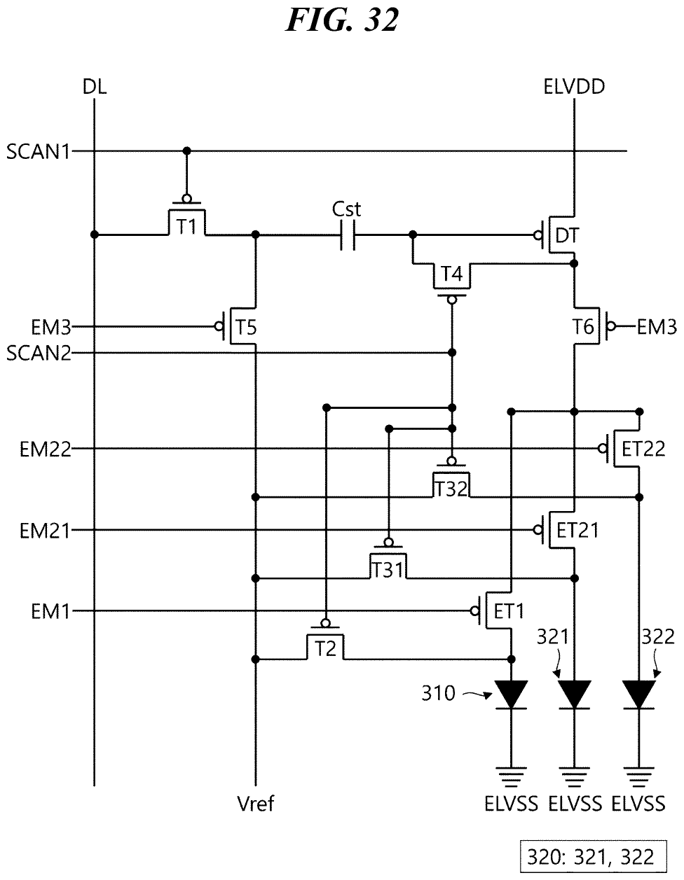

FIG. 32 is a circuit diagram illustrating a pixel circuit applicable to the first modified example of the display panel according to the second embodiment of the present specification. The same or similar reference numerals are given to the components that function substantially the same as or similar to the pixel circuit of the display device according to other embodiments described above, and descriptions thereof are omitted.

Referring to FIG. 32, the second emission control transistor ET2 may include a second-first emission control transistor ET21 and a second-second emission control transistor ET22. In addition, the third switching transistor may include a third-first switching transistor T31 and a third-second switching transistor T32. The second emission control line may include a second-first emission control line EM21 and a second-second emission control line EM22.

The second-first emission control transistor ET21 may supply the driving voltage to the second-first light-emitting element 321 in response to a light emission control signal supplied from the second-first emission control line EM21. A gate electrode of the second-first emission control transistor ET21 may be connected to the second-first emission control line EM21, a first electrode thereof may be connected to a second electrode of a sixth switching transistor T6, and a second electrode thereof may be connected to a first electrode of a second-first light-emitting element 321.

The second-second emission control transistor ET22 may supply a driving voltage to the second-second light-emitting element 322 in response to a light emission control signal supplied from the second-second emission control line EM22. A gate electrode of the second emission control transistor ET22 may be connected to the second emission control line EM22, a first electrode thereof may be connected to the second electrode of the sixth switching transistor T6, and a second electrode thereof may be connected to a first electrode of a second-second light-emitting element 322.

A first electrode of the third-first switching transistor T31 may be connected to a reference voltage line Vref, a second electrode thereof may be connected to the first electrode of the second-first light-emitting element 321, and a gate electrode thereof may be connected to a second gate line SCAN2.

A first electrode of the third-second switching transistor T32 may be connected to the reference voltage line Vref, a second electrode thereof may be connected to the first electrode of the second-second light-emitting element 322, and a gate electrode thereof may be connected to the second gate line SCAN2.

The pixel circuit according to the embodiment may selectively adjust the turn-on/off of the second-first light-emitting element 321 and the second-second light-emitting element 322. The pixel circuit of the display device according to the other embodiment described above may simultaneously adjust the turn-on/off of the second light-emitting elements 320, which may be used to adjust the turn-on/off of the second light-emitting element 320 disposed in the first display area DA1. On the other hand, The pixel circuit according to the embodiment may be used to adjust the turn-on/off of the second-first light-emitting elements 321 and the second-second light-emitting elements 322 in the third display area DA3 in which the turn-on/off of the second light-emitting elements 321 and 322 need to be selectively adjust.

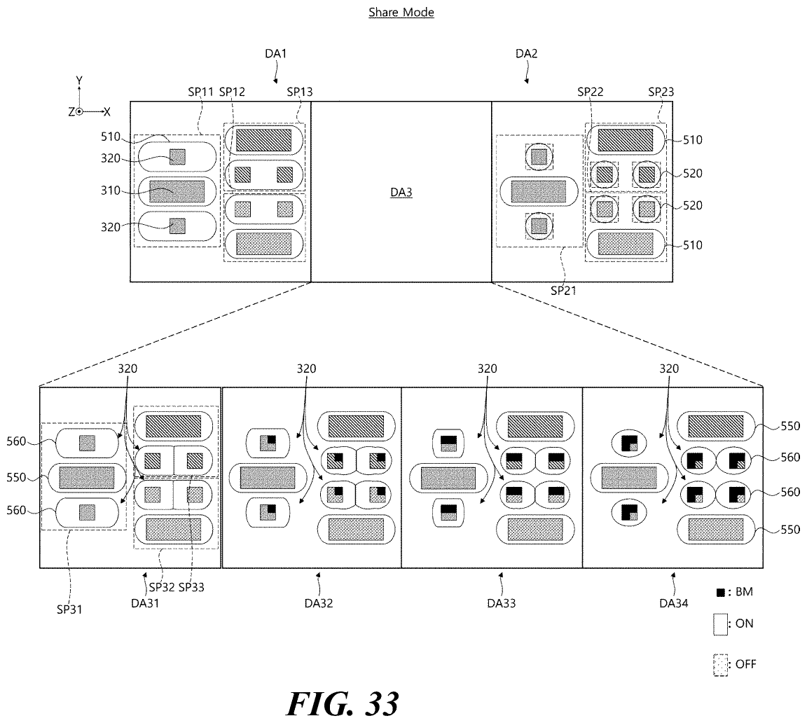

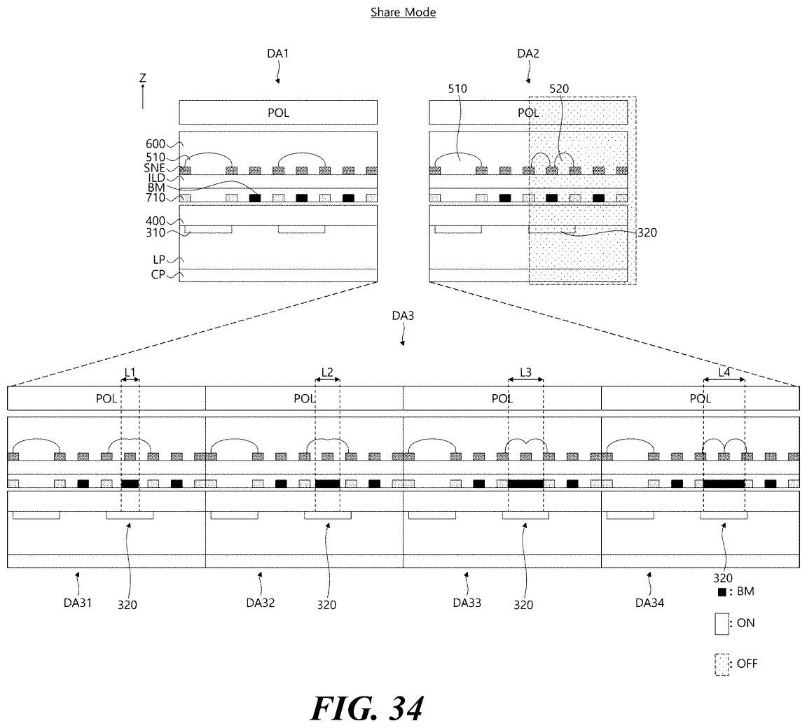

FIG. 33 is a diagram illustrating a display device including the second modified example of the display panel according to the second embodiment of the present specification. FIG. 34 is a diagram illustrating a display device including the second modified example of the display panel according to the second embodiment of the present specification. The same or similar reference numerals are given to the components that function substantially the same as or similar to the first modified example described above, and descriptions thereof are omitted.

Referring to FIGS. 33 and 34, the structures of the first display area DA1 and the second display area DA2 may be as described in all the discussions of the second embodiment above. In addition, the third viewing angle lens 550 or the fourth viewing angle lens 560, etc., may also be as described in all of the above discussions.

The second display area DA2 may be disposed in the first direction (e.g., in the X-axis direction) from the first display area DA1. The third display area DA3 disposed between them may include a third-first display area DA31, a third-second display area DA32, a third-third display area DA33, and a third-fourth display area DA34 arranged in the first direction. Each of the areas DA31, DA32, DA33, and DA34 may include a third pixel (a third-first pixel, a third-second pixel, a third-third pixel, and a third-fourth pixel).

The display panel according to the second modified example of the second embodiment may adjust the emission area of the third pixel by varying the area of the black matrix BM overlapping the light-emitting element in the plane direction (or the thickness direction) of the display panel (e.g., the Z-axis direction) progressively in the first direction. In one embodiment, the area per unit pixel in which the black matrix BM is disposed may vary progressively in the first direction. For example, the area may increase. Accordingly, the emission area of the third pixel may decrease progressively in the first direction. The embodiment in which the emission area is adjusted by a black matrix BM may be configured regardless of the modes. However, in the illustrated drawings, it is assumed that the second display area DA2 is driven in the first mode for better understanding of the emission area.

In one embodiment, an area in which the black matrix BM per unit pixel and/or per unit subpixel overlaps the second light-emitting element 320 in the thickness direction of the display panel may increase progressively in the first direction (L1<L2<L3<L4). While the embodiment illustrates overlapping the second light-emitting element 320 with the black matrix BM, but is not limited thereto, the emission area per pixel may be controlled by overlapping the first light-emitting element 310 with the black matrix BM.

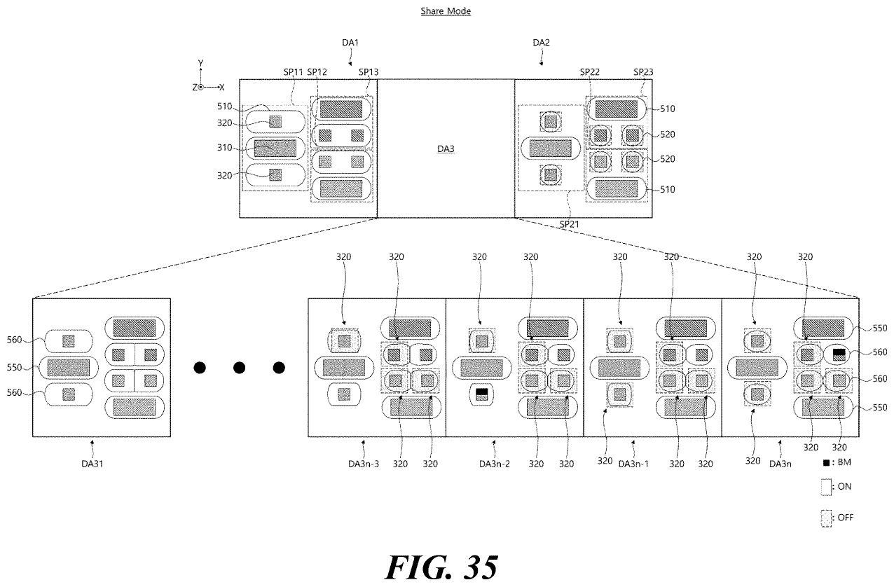

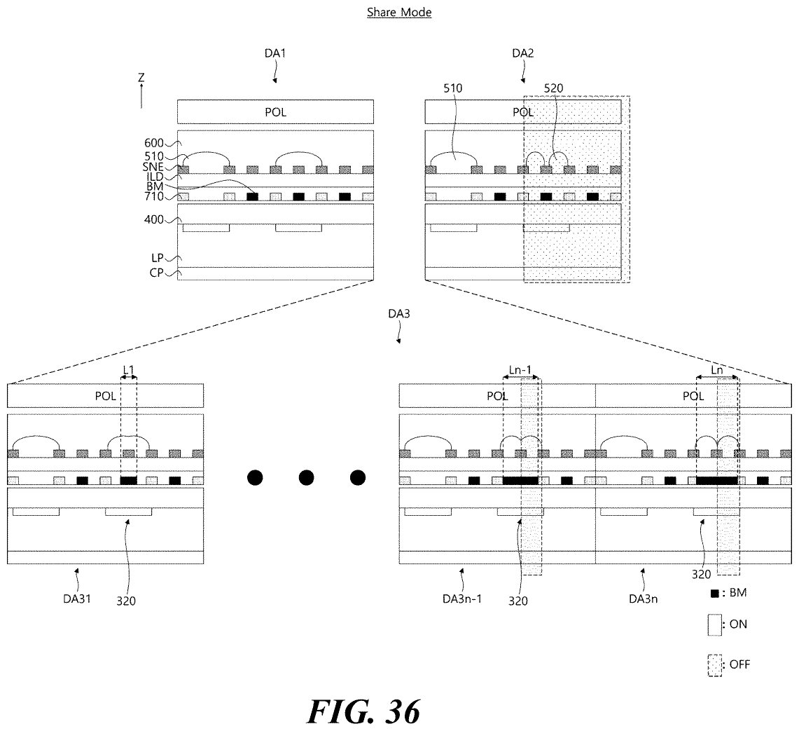

FIG. 35 is a diagram illustrating a state in which a display device including a third modified example of the display panel according to the second embodiment of the present specification is driven in a first mode; and FIG. 36 is a diagram illustrating a state in which a display device including a third modified example of the display panel according to the second embodiment of the present specification is driven in a second mode.

Referring to FIGS. 35 and 36, the structures of the first display area DA1 and the second display area DA2 may be as described in all the discussions of the second embodiment above. In addition, the third viewing angle lens 550 or the fourth viewing angle lens 560, etc., may also be as described in all of the above discussions.

The second display area DA2 may be disposed in the first direction (e.g., in the X-axis direction) from the first display area DA1. The third display area DA3 disposed between them may include a third-first display area DA31 to a third-(n)^{th} display area DA3n disposed in the first direction. Each of the areas DA31, DA3n-3, DA3n-2, DA3n-1, and DA3n may include a third pixel (a third-first pixel, a third-(n-3)^{th} pixel, a third-(n-2)^{th} pixel, a third-(n-4)^{th} pixel, a third-(n-5)^{th} pixel, and a third-(n)^{th} pixel).

The display panel according to the third modified example of the second embodiment may adjust the emission area of the third pixel by varying the number of the turned-off light-emitting elements and the area of the black matrix BM overlapping the light-emitting element in the plane direction (or the thickness direction) of the display panel (e.g., the Z-axis direction) progressively in the first direction.

In one embodiment, the number of light-emitting elements disposed and turned off in the third pixel may vary progressively in the first direction. For example, the number of light-emitting elements disposed and turned off in the third pixel may increase progressively in the first direction. Accordingly, the emission area of the third pixel may decrease progressively in the first direction. At the same time, the color implemented by the subpixels to be turned off may vary progressively in the first direction. At the same time, the area per unit pixel in which the black matrix BM is disposed may vary progressively in the first direction. For example, the area may increase. Accordingly, the emission area of the third pixel may decrease progressively in the first direction.

In one embodiment, an area in which the black matrix BM per unit pixel and/or per unit subpixel overlaps the second light-emitting element 320 in the thickness direction of the display panel may increase progressively in the first direction (L1< . . . . Ln-1<Ln).

Although the embodiments of the present disclosure have been described in more detail with reference to the accompanying drawings, the present disclosure is not necessarily limited to such embodiments, and may be variously modified within the scope thereof without departing from the technical spirit of the present disclosure. Therefore, the embodiments disclosed in the present disclosure are provided for illustrative purposes only and are not intended to limit the technical concept of the present disclosure, and the scope of the technical concept of the present disclosure is not limited thereto. Therefore, it should be understood that the embodiments described above are illustrative in all aspects and do not limit the present disclosure. The scope of protection of the present disclosure should be construed on the basis of the following claims, and all technical concepts within the equivalent scope thereof should be construed as falling within the scope of the present disclosure.

### DESCRIPTION OF REFERENCE NUMERALS

10: Display panel
310: First light-emitting element
320: Second light-emitting element
510: First viewing angle lens
520: Second viewing angle lens
530: First dummy lens
540: Second dummy lens
DA1: First display area
DA2: Second display area
DA3: Third display area
PIX1: Second pixel PIX2: Second pixel

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a first display area including a plurality of first pixels, a first viewing angle lens disposed on the plurality of first pixels, and a first dummy lens; and
a second display area including a plurality of second pixels, a first viewing angle lens and a second viewing angle lens disposed on the plurality of second pixels, and a second dummy lens,
wherein a shape of the first dummy lens is different from a shape of the second dummy lens.

2. The display panel of claim 1, wherein:
a first sum of an area of the first viewing angle lens in the first display area and an area of the first dummy lens is equal to:
a second sum of an area of the first viewing angle lens in the second display area, an area of the second viewing angle lens in the second display area, and an area of the second dummy lens.

3. The display panel of claim 1, wherein:
a first pixel in the first display area includes a first-first subpixel, a first-second subpixel, and a first-third subpixel emitting light of different wavelengths,
a second pixel in the second display area includes a second-first subpixel, a second-second subpixel, and a second-third subpixel emitting light of different wavelengths, and
the first-first subpixel, the first-second subpixel, the first-third subpixel and the second-first subpixel, the second-second subpixel, and the second-third subpixel each includes a first light-emitting element and a second light-emitting element.

4. The display panel of claim 3, wherein:
the first viewing angle lens in the first display area is disposed on the first light-emitting element and the second light-emitting element,
the first viewing angle lens in the second display area is disposed on the first light-emitting element,
the second viewing angle lens in the second display area is disposed on the second light-emitting element, and
a shape of the first viewing angle lens is different from a shape of the second viewing angle lens.

5. The display panel of claim 4, wherein a number of the first viewing angle lenses in the first display area is greater than a number of the first viewing angle lenses in the second display area.

6. The display panel of claim 4, wherein a sum of the number of the first viewing angle lenses and the second viewing angle lenses in the second display area is greater than the number of the first viewing angle lenses in the first display area.

7. The display panel of claim 4, wherein:
the first dummy lens has a same shape as the second viewing angle lens in the second display area, and
the second dummy lens has a same shape as the first viewing angle lens in the first display area.

8. The display panel of claim 4, wherein a position of the first dummy lens within the first pixel corresponds to a position of the second dummy lens within the second pixel.

9. The display panel of claim 4, wherein the shape of the second dummy lens is different from the shape of the first viewing angle lens.

10. The display panel of claim 3, wherein:
the first light-emitting element and the second light-emitting element of the first pixel are configured to be driven simultaneously, and
the first light-emitting element and the second light-emitting element of the second pixel are configured to be selectively driven according to modes.

11. The display panel of claim 1, further comprising:
a third display area disposed between the first display area and the second display area, wherein:
the third display area includes a plurality of third pixels, a third viewing angle lens disposed on the plurality of third pixels, and a third dummy lens, and
a shape of the third dummy lens varies progressively from the first display area toward the second display area.

12. The display panel of claim 11, wherein the shape of the third viewing angle lens varies progressively from the first display area toward the second display area.

13. A display panel comprising:
a first display area including a plurality of first pixels and a plurality of first viewing angle lenses disposed on the plurality of first pixels;
a second display area including a plurality of second pixels, and a plurality of first viewing angle lenses and a plurality of second viewing angle lenses disposed on the plurality of second pixels; and
a third display area including a plurality of third pixels, and a plurality of third viewing angle lenses and a plurality of fourth viewing angle lenses disposed on the plurality of third pixels, the third display area being disposed between the first display area and the second display area, wherein:
the second display area is configured to selectively emit any one of the first light-emitting element and the second light-emitting element disposed in each subpixel of the second pixel according to a first mode and a second mode in which the viewing angle is variable,
the first display area is configured to emit all of the first light-emitting element and the second light-emitting element disposed in each subpixel of the first pixel in the first mode and the second mode, and
shapes of the plurality of third viewing angle lenses and the plurality of fourth viewing angle lenses vary progressively in a first direction from the first display area toward the second display area.

14. The display panel of claim 13, wherein:
a sum of areas of the plurality of first viewing angle lenses in the first display area,
a sum of areas of the plurality of first viewing angle lenses and the plurality of second viewing angle lenses in the second display area, and
a sum of areas of the plurality of third viewing angle lenses and the plurality of fourth viewing angle lenses in the third display area are equal to each other.

15. A display device comprising:
a display panel;
a data driver configured to drive the display panel; and
a gate drive configured to drive the display panel,
wherein the display panel includes:
a first display area including a plurality of first pixels, a plurality of first viewing angle lenses disposed on the plurality of first pixels, and a first dummy lens; and
a second display area including a plurality of second pixels, a plurality of first viewing angle lenses and a plurality of second viewing angle lenses disposed on the plurality of second pixels, and a second dummy lens, and
wherein the first dummy lens and the second dummy lens have different shapes.

16. The display device of claim 15, wherein:
a sum of areas of the first viewing angle lenses in the first display area and an area of the first dummy lens is equal to
a sum of areas of the first viewing angle lenses in the second display area, areas of the second viewing angle lenses in the second display area, and an area of the second dummy lens.

17. The display device of claim 15, wherein:
the first pixel includes a first-first subpixel, a first-second subpixel, and a first-third subpixel emitting light of different wavelengths,
the second pixel includes a second-first subpixel, a second-second subpixel, and a second-third subpixel emitting light of different wavelengths, and
the first-first subpixel to the first-third subpixel and the second-first subpixel to the second-third subpixel each includes a first light-emitting element and a second light-emitting element.

18. The display device of claim 17, wherein:
the plurality of first viewing angle lenses in the first display area are disposed on the first light-emitting element and the second light-emitting element,
the plurality of the first viewing angle lenses in the second display area are disposed on the first light-emitting element,
the plurality of second viewing angle lenses in the second display area are disposed on the second light-emitting element, and
a shape of a first viewing angle lens is different from a shape of a second viewing angle lens.

19. A display panel comprising:
a first display area including a plurality of first pixels and a plurality of first viewing angle lenses disposed on the plurality of first pixels;
a second display area including a plurality of second pixels, and a plurality of first viewing angle lenses and a plurality of second viewing angle lenses disposed on the plurality of second pixels; and
a third display area including a plurality of third pixels, and a plurality of third viewing angle lenses and a plurality of fourth viewing angle lenses disposed on the plurality of third pixels, the third display area being disposed between the first display area and the second display area,
wherein the first display area is configured to emit all of a first light-emitting element and a second light-emitting element disposed in each subpixel of the first pixel according to a first mode and a second mode in which the viewing angle is variable, and
the second display area is configured to selectively emit any one of the first light-emitting element or the second light-emitting element disposed in each subpixel of the second pixel according to the first mode and the second mode, and
wherein an emission area of the third pixel in the first mode varies progressively in a first direction from the first display area toward the second display area.

20. The display panel of claim 19, wherein:
the first pixel includes a first-first subpixel, a first-second subpixel, and a first-third subpixel emitting light of different wavelengths,
the second pixel includes a second-first subpixel, a second-second subpixel, and a second-third subpixel emitting light of different wavelengths, and
the first-first subpixel to the first-third subpixel and the second-first subpixel to the second-third subpixel each includes a first light-emitting element and a second light-emitting element.

21. The display panel of claim 20, wherein:
the plurality of first viewing angle lenses in the first display area are disposed on the first light-emitting element and the second light-emitting element,
the plurality of the first viewing angle lenses in the second display area are disposed on the first light-emitting element,
the plurality of second viewing angle lenses in the second display area are disposed on the second light-emitting element, and
a shape of a first viewing angle lens is different from a shape of a second viewing angle lens.

22. The display panel of claim 21, wherein the number of the first viewing angle lenses in the first display area is greater than the number of the first viewing angle lenses in the second display area.

23. The display panel of claim 20, wherein the shapes of the plurality of third viewing angle lenses and the plurality of fourth viewing angle lenses vary progressively in a first direction from the first display area toward the second display area.

24. The display panel of claim 19, wherein:
in the first mode, the number of light-emitting elements disposed and turned off in the third pixel varies progressively in the first direction.

25. The display panel of claim 19, wherein:
the third pixel includes a third-first subpixel, a third-second subpixel, and a third-third subpixel emitting light of different wavelengths, and
the third-first subpixel to the third-third subpixel each includes a first light-emitting element and a second light-emitting element.

26. The display panel of claim 25, wherein the third display area includes:
a third-first display area including a third-first pixel; and
a third-second display area including a third-second pixel disposed in the first direction from the third-first pixel, and
wherein, in the first mode, the number of light-emitting elements disposed and turned off in the third-second pixel is greater than the number of light-emitting elements disposed and turned off in the third-first pixel.

27. The display panel of claim 26, wherein the third-first subpixel to the third-third subpixel are configured to implement any one color selected from the group consisting of red, green, or blue, respectively, without overlapping each other, and
wherein, in the first mode, the third-second pixels includes:
a third-second subpixel including a turned-off light-emitting element.

28. The display panel of claim 27, wherein the third display area further includes:
a third-third display area including a third-third pixel disposed in the first direction from the third-second pixel,
wherein, in the first mode, the third-third pixel includes:
a third-second subpixel including a turned-off light-emitting element and a third-first subpixel including a turned-off light-emitting element.

29. The display panel of claim 28, wherein the third display area further includes:
a third-fourth display area including a third-fourth pixel disposed in the first direction from the third-third pixel, and
wherein, in the first mode, the third-fourth pixel includes:
a third-second subpixel including a turned-off light-emitting element, a third-first subpixel including a turned-off light-emitting element, and a third-third subpixel including a turned-off light-emitting element.

30. The display panel of claim 29, wherein:
the third-first subpixels disposed in the third display area implement a red color,
the third-second subpixels disposed in the third display area implement a green color, and
third-third subpixels disposed in the third display area implement a blue color.

31. The display panel of claim 19, wherein, in the first mode,
the emission area of the third pixel decreases progressively in the first direction.

32. The display panel of claim 31, wherein:
the third pixel includes a third-first subpixel, a third-second subpixel, and a third-third subpixel emitting light of different wavelengths,
the third-first subpixel to the third-third subpixel each includes a first light-emitting element and a second light-emitting element, and
the shapes of the plurality of third viewing angle lenses and the plurality of fourth viewing angle lenses vary progressively in the first direction.

33. The display panel of claim 32, wherein:
the plurality of the third viewing angle lenses is disposed on the first light-emitting element,
the plurality of fourth viewing angle lenses is disposed on the second light-emitting element, and
the shapes of the fourth viewing angle lenses vary progressively in the first direction.

34. The display panel of claim 33, wherein, in the first mode,
the emission area of the second light-emitting element varies progressively in the first direction.

35. The display panel of claim 19, wherein:
the third pixel includes a third-first subpixel, a third-second subpixel, and a third-third subpixel emitting light of different wavelengths,
the third-first subpixel to the third-third subpixel each includes a first light-emitting element and a second light-emitting element, and
the third display area further includes a black matrix disposed on the second light-emitting element.

36. The display panel of claim 35, wherein the area in which the second light-emitting element disposed in the third display area and the black matrix overlap varies progressively in the first direction.
